(19) United States
(12) Patent Application Publication
(10) Pub. No.: US 2026/0020430 A1
(43) Pub. Date: Jan. 15, 2026

(54) COMPOSITE MATERIAL AND PREPARATION METHOD THEREFOR, QUANTUM DOT LIGHT-EMITTING DIODE

(71) Applicant: TCL Technology Group Corporation, Huizhou, Guangdong (CN)

(72) Inventor: Wenlin LIANG, Huizhou, Guangdong (CN)

(73) Assignee: TCL Technology Group Corporation, Huizhou, Guangdong (CN)

(21) Appl. No.: 19/111,749

(22) PCT Filed: Sep. 13, 2023
(86) PCT No.: PCT/CN2023/118641

§ 371 Date: Mar. 13, 2025

(30) Foreign Application Priority Data
Sep. 14, 2022 (CN) 202211113476.7

(51) Int. Cl. H10K 50/115; B82Y 30/00; C09K 11/02; C09K 11/06; H10K 102/00

(52) U.S. Cl. CPC H10K 50/115; B82Y 30/00; C09K 11/02; C09K 11/06; H10K 2102/351

(57) ABSTRACT

Provided are a composite material and a preparation method therefor, and a quantum dot light-emitting diode. The composite material comprises a quantum dot and a ligand bonded to the surface of the quantum dot, wherein the ligand is an anthracene compound, and the anthracene compound comprises at least one of anthraquinone, anthranol, anthrone, an anthraquinone derivative, an anthranol derivative and an anthrone derivative. The ligand of the composite material at least has a strong adsorption group such as C═O or —OH, making the ligand easier to adsorb on the surface of the quantum dot compared with impurity ions, such that defects on the surface of the quantum dot are prevented from being filled with the impurity ions, and the electrical conductivity of the composite material is improved.

The application claims priority to Chinese Application No. 202211113476.7, entitled “COMPOSITE MATERIAL AND PREPARATION METHOD THEREFOR, QUANTUM DOT LIGHT-EMITTING DIODE”, filed on Sep. 14, 2022. The entire disclosures of the above application are incorporated herein by reference.

### TECHNICAL FIELD

The present disclosure relates to a field of semiconductor materials, and in particular, to a composite material and a preparation method therefor, and a quantum dot light-emitting diode.

### BACKGROUND

Semiconductor quantum dots, also known as semiconductor nanocrystals, have great application prospects in quantum dot light-emitting devices, displays, and other optoelectronic devices due to their unique optical properties. Especially, the solution method has attracted more and more attention in the fields of electronic and optoelectronic devices because of its advantages such as good synthesis stability, high synthesis quality, simple synthesis method and low cost.

Semiconductor quantum dots are generally prepared by using inorganic salts or organometallic compounds as reaction precursors and organic solvents as reaction mediums. Organic ligands are often dynamically adsorbed on a surface of a nanocrystal. Typical organic ligands include long chain carboxylic acid and phosphonic acid (such as oleic acid and octadecylphosphonic acid), thiol (dodecanethiol), alkylphosphine, alkylphosphine oxide (trioctylphosphine TOP and trioctylphosphine TOPO), alkylamines (hexadecylamine) and the like. The ligands on the surface play a crucial role not only in the synthesis of nanocrystals but also in controlling the process of nanocrystal particle formation.

The structure of these ligands offers excellent chemical adaptability and stability, but there are also some issues. The most critical issue is that, due to the relatively large molecular volume or long molecular chains of most organic ligands, they act as insulating layers between nanocrystal particles. This hinders charge transport, resulting in poor performance of the fabricated devices. If ligands are not added, the surfaces of the nanocrystals prepared via the solution method exhibit high-density defects and poor solubility. These defects can induce exciton recombination, leading to Auger recombination, which significantly reduces efficiency.

Therefore, the prior art remains to be improved and developed.

### SUMMARY

Therefore, the present disclosure provides a composite material and a preparation method therefor, and a quantum dot light-emitting diode.

The present disclosure provides a composite material including a quantum dot and a ligand bound to a surface of the quantum dot. The ligand is an anthracene compound, and the anthracene compound includes at least one of anthraquinone, anthranol, anthrone, an anthraquinone derivative, an anthranol derivative, and an anthrone derivative.

Optionally, in some embodiments of the present disclosure, the anthracene compound includes at least one compound having a structure represented by any one of formulaes (1) to (3):

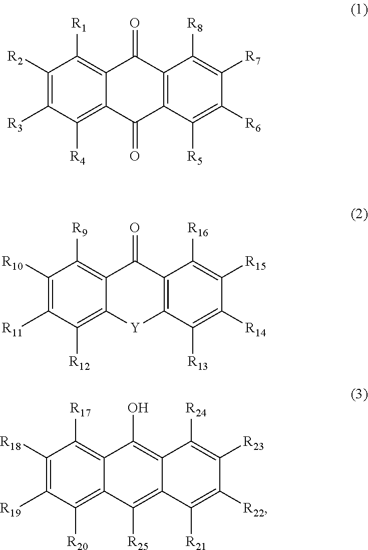

where Y is selected from CR₂₆R₂₇ or NR₂₈; R₁ to R₂₈ are independently selected from one or more of hydrogen, deuterium, alkyl, aryl, keto, cyano, hydroxyl, nitro, amino and halogen groups, or R₁ to R₂₈ are independently selected from one or more of the above groups and two adjacent substituents of R₁ to R₂₈ are bonded to form a ring.

Optionally, in some embodiments of the present disclosure, carboxyl, amino, halogen or halogenated alkyl is set as an active group;
at least one of R₁ to R₈ is selected from active groups; and/or,
Y is selected from CR₂₆R₂₇, and at least one of R₉-R₁₆ and R₂₆-R₂₇ is selected from the active groups; or Y is selected from NR₂₈, and at least one of R₉ to R₁₆ and R₂₈ is selected from the active groups; and/or,
at least one of R₁₇ to R₂₅ is selected from the active groups.

Optionally, in some embodiments of the present disclosure, Y is selected from CR₂₆R₂₇, and at least one of R₁₁ to R₁₄ and R₂₆ to R₂₇ is selected from the active groups, or Y is selected from NR₂₈, and at least one of R₁₁ to R₁₄ and R₂₈ is selected from the active groups; and/or,
at least one of R₁₉ to R₂₂ and R₂₅ includes the active group.

Optionally, in some embodiments of the present disclosure, at least one of R₁-R₈ is selected from hydrogen or deuterium; and/or,
at least one of R₉ to R₁₆ is selected from hydrogen or deuterium; and/or,
at least one of R₁₇ to R₂₅ is selected from hydrogen or deuterium.

Optionally, in some embodiments of the present disclosure, the number of carbon atoms in the alkyl is less than or equal to 20; and/or,
the number of ring atoms in the aryl is less than or equal to 60.

Optionally, in some embodiments of the present disclosure, the anthracene compound includes at least one compound having a structure represented by any one of the following structural formulas (4) to (30):

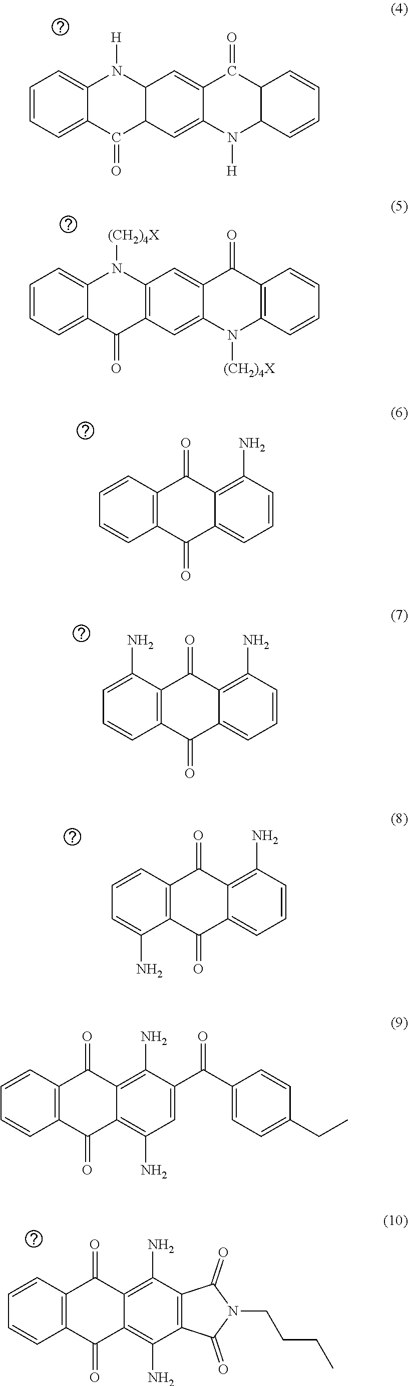

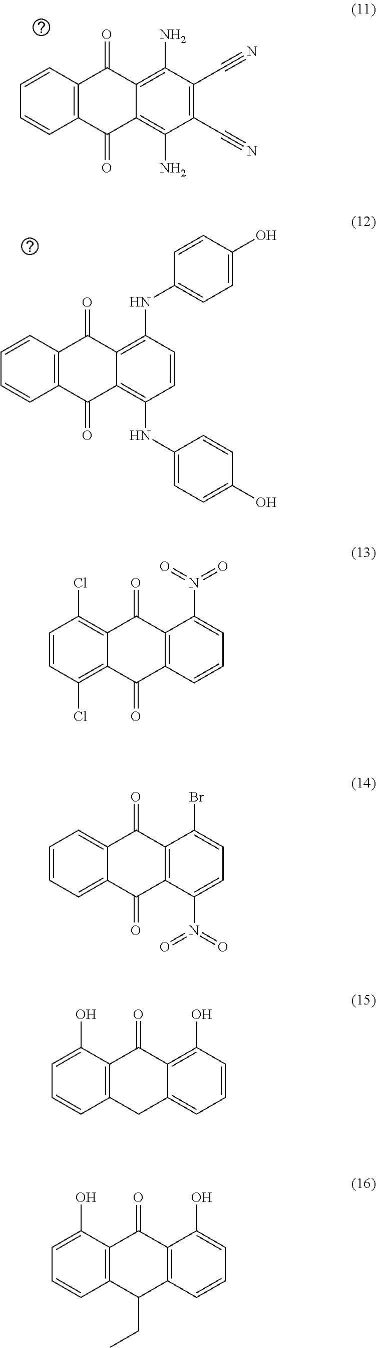

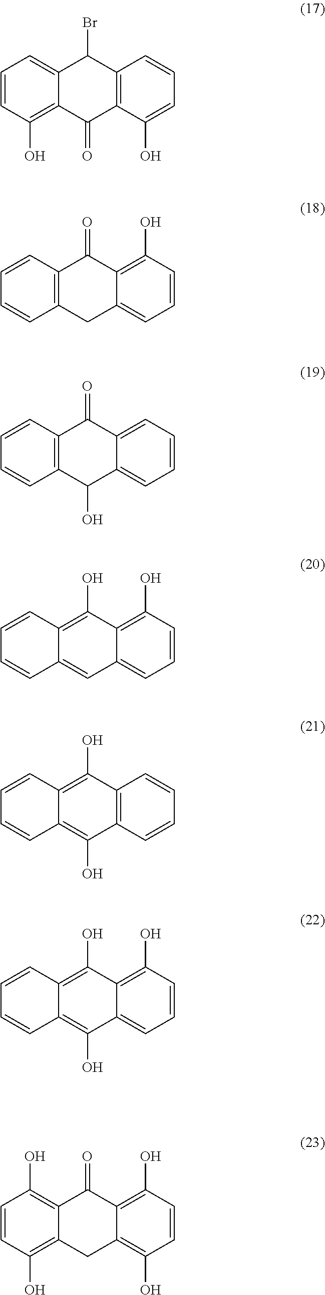

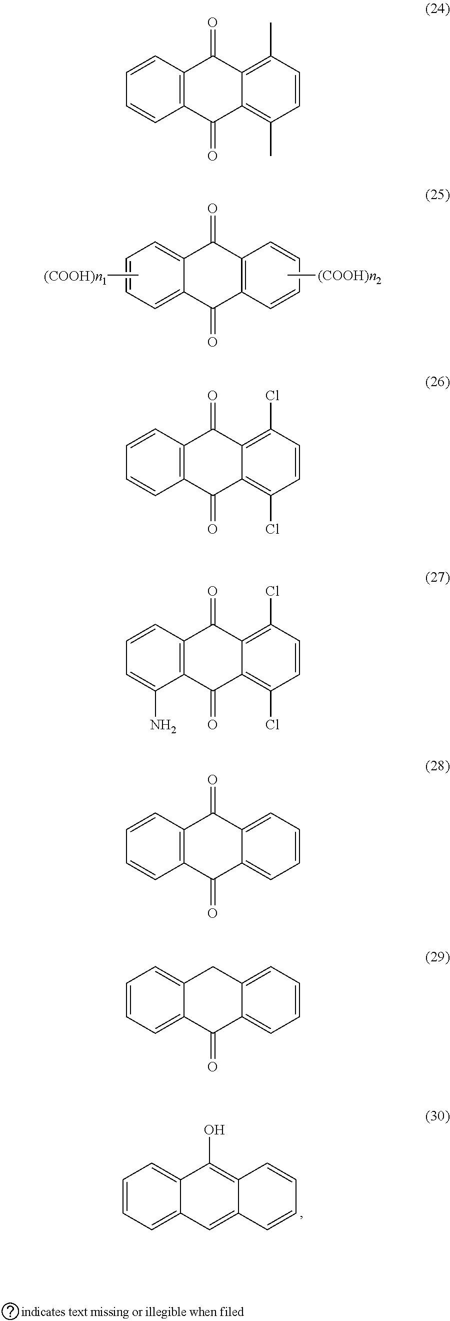

where n is a positive integer equal to or less than 20, X is Cl, Br, or I; n₁ and n₂ are independently selected from 0, 1, 2, 3 or 4, and a sum of n₁ and n₂ is greater than or equal to 1.

Optionally, in some embodiments of the present disclosure, a molar ratio of the quantum dot and the ligand in the composite material is 1:(1 to 10); and/or,
the quantum dot is selected from at least one of a single structure quantum dot and a core-shell structure quantum dot; the single structure quantum dot is selected from at least one of a group II-VI compound, a group IV-VI compound, a group III-V compound, and a group I-III-VI compound, the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, the group III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb, the group I-III-VI compound is selected from one or more of CuInS₂, CuInSe₂, and AgInS₂; a core of the core-shell structure quantum dot is selected from any one of the single structure quantum dots, and a shell material of the core-shell structure quantum dot is selected from at least one of CdS, CdTe, CdSeTe, CdZnSe, CdZnS, CdSeS, ZnSe, ZnSeS, and ZnS.

The present disclosure provides a method for preparing a composite material including:
providing a core cation precursor, a ligand, a core anion precursor, and an organic solvent;
mixing the core cation precursor, the ligand and the organic solvent, and then adding the core anion precursor to react to obtain a first solution containing a quantum dot core and the ligand;
injecting a shell cation source and a shell anion source into the first solution, forming a first shell layer on a surface of the quantum dot core, and repeating the steps n times to sequentially obtain a second shell layer to an (n+1)th shell layer to obtain a composite material in which the ligand is connected to a surface of the (n+1)th shell layer, wherein n is an integer equal to or greater than 0;
wherein the ligand is an anthracene compound, and the anthracene compound includes at least one of anthraquinone, anthranol, anthrone, an anthraquinone derivative, an anthranol derivative, and an anthrone derivative.

Optionally, in some embodiments of the present disclosure, the anthracene compound includes at least one compound having a structure represented by any one of formulaes (1) to (3):

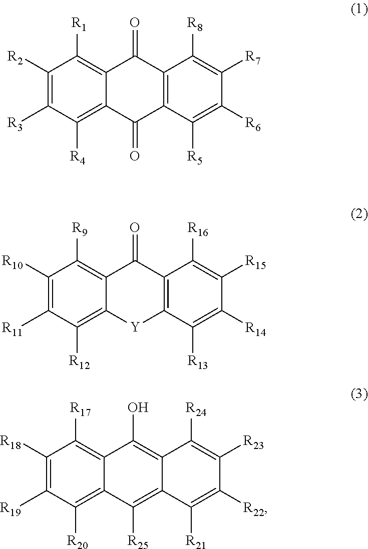

where Y is selected from CR₂₆R₂₇ or NR₂₈; R₁ to R₂₈ are independently selected from one or more of hydrogen, deuterium, alkyl, aryl, keto, cyano, hydroxyl, nitro, amino and halogen groups, or R₁ to R₂₈ are independently selected from one or more of the above groups and two adjacent substituents of R₁ to R₂₈ are bonded to form a ring.

Optionally, in some embodiments of the present disclosure, the anthracene compound includes at least one compound having a structure represented by any one of the following structural formulas (4) to (30):

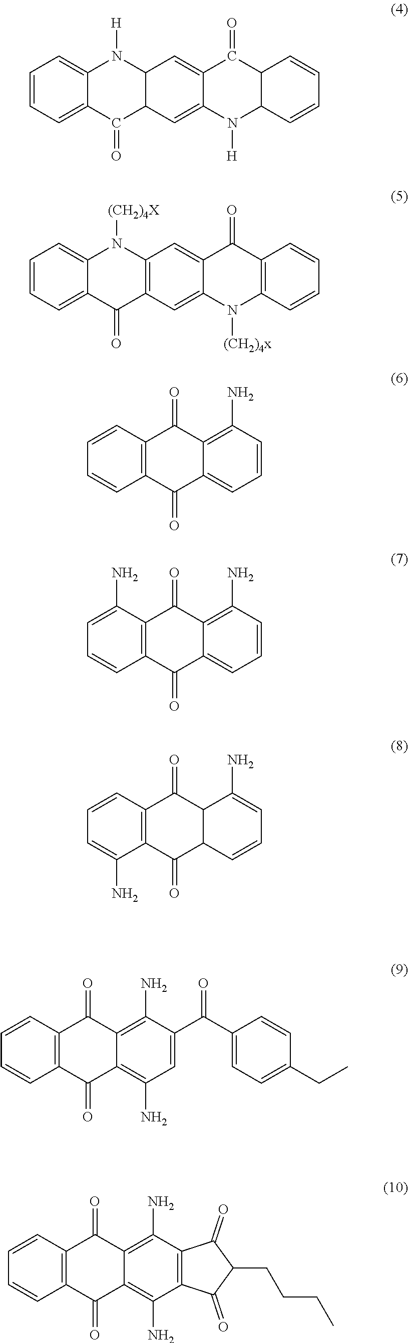

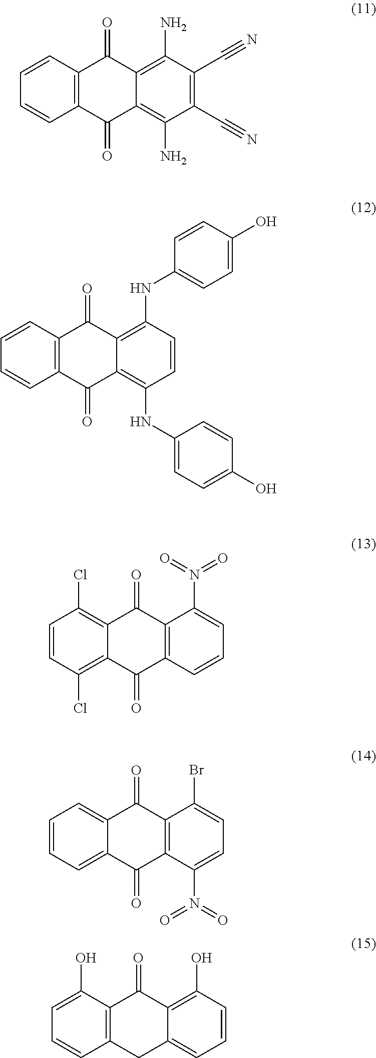

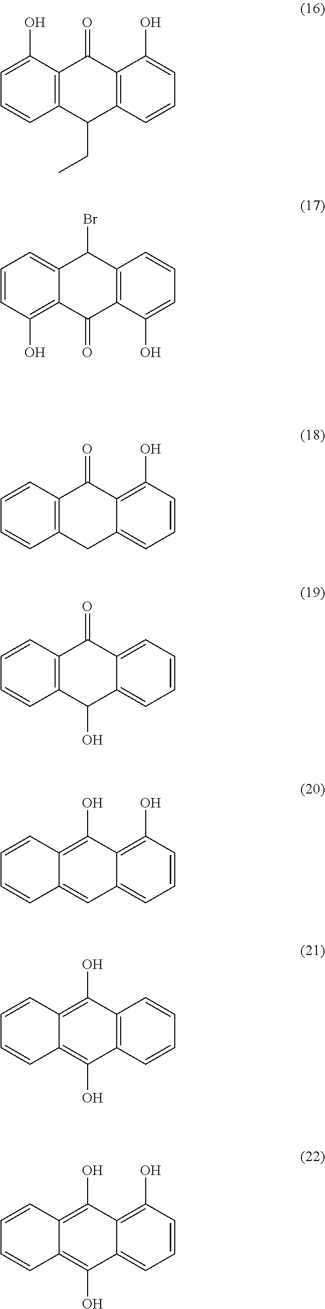

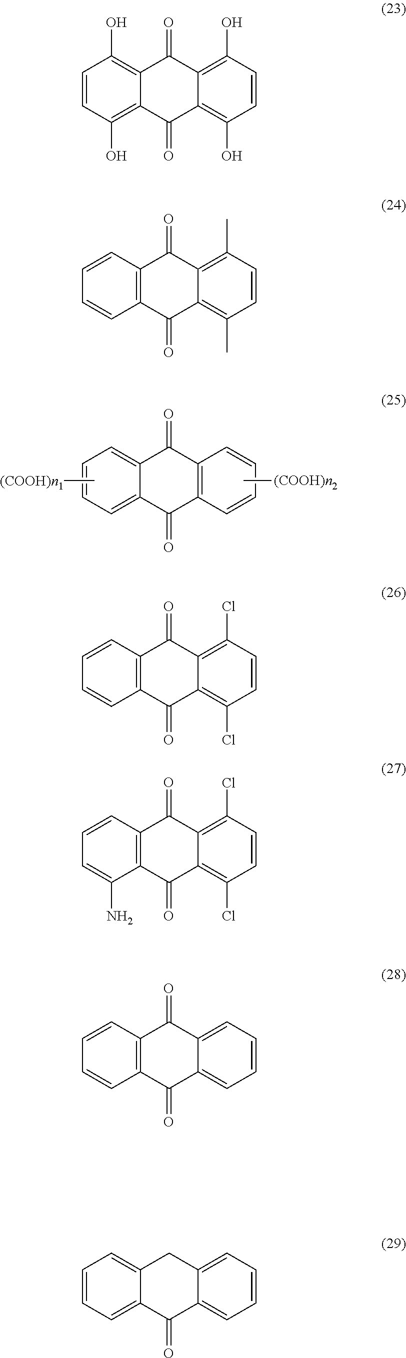

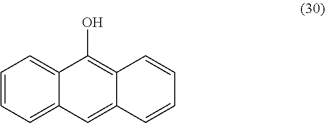

where n is a positive integer equal to or less than 20, X is CL, Br, or I; n₁ and n₂ are independently selected from 0, 1, 2, 3 or 4, and a sum of n₁ and n₂ is greater than or equal to 1.

Optionally, in some embodiments of the present disclosure, the ligand includes a compound having a structure represented by structural formula (5);
prior to the step of providing the core cation precursor, the ligand, the core anion precursor, and the organic solvent, the method further including:
providing a first compound, quinacridone, sodium hydride, tetrabutylammonium bromide, and tetrahydrofuran, where the first compound has the structural formula X(CH₂)ₙX, with X being said Cl, Br or I;
mixing quinacridone, sodium hydride, tetrabutylammonium bromide and tetrahydrofuran, heating at 80-100° C., then adding the first compound, and continuing to heat at 50-70° C. to obtain a compound having the structure represented by structural formula (5).

Optionally, in some embodiments of the present disclosure, a molar ratio of quinacridone, the first compound, sodium hydride, and tetrabutylammonium bromide is 1:(1-5):(5-8):(1-3); and/or,
a time of heating at 80-100° C. is 1-2 h; and/or,
a time of heating at 50-70° C. is 12-24 h.

Optionally, in some embodiments of the present disclosure, the ligand comprises a compound having a structure represented by structural formula (25);
prior to the step of providing the core cation precursor, the ligand, the core anion precursor, and the organic solvent, the method further including:
providing a second compound, glacial acetic acid, and chromium trioxide, where the second compound has a structure represented by formula (31), and a substitution site of —CH₃ in the second compound is the same as a substitution site of —COOH in the compound having a structure represented by structural formula (25);
mixing the second compound, glacial acetic acid, and chromium trioxide, and heating at 55 to 70° C., to obtain a compound having a structure represented by structural formula (25);

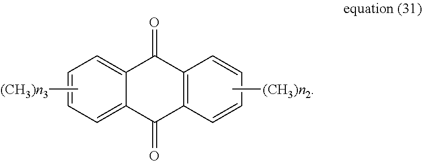

Optionally, in some embodiments of the present disclosure, the core cation precursor includes at least one of a cadmium source, a zinc source, an indium source, a copper source, and a silver source; and/or,
the core anion precursor includes at least one of a selenium source, a sulfur source, a tellurium source, and a phosphorus source; and/or,
the organic solvent includes an organic compound having 10 to 22 carbon atoms selected from at least one of alkanes, olefins, halogenated hydrocarbons, aromatic hydrocarbons, ethers, amines, ketones, and esters; and/or,
the shell cation source includes at least one of a cadmium source and a zinc source; and/or,
the shell anion source includes at least one of a selenium source, a sulfur source, a tellurium source, and a phosphorus source; and/or,
in the step of mixing the core cation precursor, the ligand and the organic solvent, and then adding the core anion precursor to react to obtain the first solution containing the quantum dot core and the ligand, a temperature of reacting is 180° C. to 320° C.; and/or,
the step of injecting a shell cation source and a shell anion source into the first solution, forming a first shell layer on a surface of the quantum dot core, and repeating the steps n times to sequentially obtain a second shell layer to an (n+1)th shell layer to obtain a composite material in which the ligand is connected to a surface of the (n+1)th shell layer, wherein n is an integer equal to or greater than 0, is performed at 240-320° C.

The present disclosure provides a quantum dot light-emitting diode including an anode, a light-emitting layer, and a cathode which are stacked, wherein a material of the light-emitting layer includes a composite material including the composite material as described above, or the composite material prepared by the method as described above.

Optionally, in some embodiments of the present disclosure, the anode and the cathode are independently selected from a metal electrode, a carbon-silicon material electrode, a metal oxide electrode, or a composite electrode, a material of the metal electrode is selected from at least one of Ag, Al, Mg, Au, Cu, Mo, Pt, Ca, and Ba, a material of the carbon-silicon material electrode is selected from at least one of silicon, graphite, carbon nanotubes, graphene, and carbon fiber, a material of the metal oxide electrode is selected from at least one of indium doped tin oxide, fluorine doped tin oxide, antimony doped tin oxide, aluminum doped zinc oxide, gallium doped zinc oxide, indium doped zinc oxide, magnesium doped zinc oxide and aluminum doped magnesium oxide, and the composite electrode is selected from at least one of AZO/Ag/AZO, AZO/Al/AZO, ITO/Ag/ITO, ITO/Al/ITO, ZnO/Ag/ZnO, ZnO/Al/ZnO, TiO2/Ag/TiO2, TiO2/Al/TiO2, ZnS/Ag/ZnS and ZnS/Al/ZnS.

### BRIEF DESCRIPTION OF DRAWINGS

In order to more clearly explain the technical solutions in the embodiments of the present disclosure, the accompanying drawings that need to be used in the description of the embodiments will be briefly introduced below, and it is obvious that the accompanying drawings in the following description are only some embodiments of the present disclosure, and for those skilled in the art, other accompanying drawings can be obtained from these accompanying drawings without making creative labor.

FIG. 1 is a flow chart of a method for preparing a composite material according to a first embodiment of the present disclosure.

FIG. 2 is a flow chart of a method for preparing a composite material according to a second embodiment of the present disclosure;

FIG. 3 is a flow chart of a method for preparing a composite material according to a third embodiment of the present disclosure;

FIG. 4 is a schematic structural diagram of a quantum dot light-emitting diode according to an embodiment of the present disclosure.

FIG. 5 is a schematic structural diagram of a quantum dot light-emitting diode according to another embodiment of the present disclosure.

Reference numeral: 100, quantum dot light emitting diode; 10, anode; 20, light-emitting layer; 30, electron transport layer; 40, cathode; 50, hole transport layer; 60, hole injection layer.

### DETAILED DESCRIPTION

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure. Furthermore, it should be understood that the detailed description described herein is for illustration and explanation of the present disclosure only, and is not intended to limit the present disclosure. In the present disclosure, unless otherwise stated, location words such as “upper” and “lower” are used to specifically refer to the plane direction in the drawings. Additionally, in the description of the present disclosure, the term “including” means “including but not limited to”. Various embodiments of the present disclosure may exist in a range of forms. It should be understood that the description in a range form is for convenience and brevity only, and should not be construed as a hard limitation on the scope of the present disclosure. Accordingly, it should be considered that the stated range description has specifically disclosed all possible sub-ranges as well as single numerical values within the range. For example, it should be considered that a range from 1 to 6 has specifically disclosed subranges, such as from 1 to 3, from 1 to 4, from 1 to 5, from 2 to 4, from 2 to 6, from 3 to 6, and the like, and single numbers within the range, such as 1, 2, 3, 4, 5, and 6, which apply regardless of the range. In addition, whenever a numerical range is indicated herein, it is meant to include any referenced number (fraction or integer) within the indicated range.

In the present disclosure, “and/or” describes the association relationship of the association object, and indicates that there may be three kinds of relationships, for example, A and/or B, which may indicate that A exists alone, A and B exist at the same time, and B exists alone. A and B may be singular or plural.

In the present disclosure, “at least one” refers to one or more, and “a plurality” refers to two or more. “at least one of the following”, or similar expressions thereof refer to any combination of these items, including any combination of single or plural items. For example, “at least one of a, b, or c”, or “at least one of a, b, and c” may all mean: a, b, c, a-b (that is, a and b), a-c, b-c, or a-b-c, wherein a, b, and c, may be a single item or a plurality of items, respectively.

### Term Definition

Unless otherwise indicated, terms used in the present disclosure have the following definitions.

In the present disclosure, atoms are bonded to form a ring, resulting in a structural compound (e.g., a monocyclic compound, a fused ring compound, or a polycyclic compound). The “number of ring atoms” refers to the number of atoms constituting the ring itself in the structural compound. The structural compound is a carbocyclic compound, and may be a heterocyclic compound containing a non-carbon atom. When the ring is substituted with a substituent, the atoms contained in the substituent are not included in the ring-forming atoms. The same applies to the “number of ring atoms” described below unless otherwise specified. For example, the number of ring atoms of the benzene ring is 6, the number of ring atoms of the naphthalene ring is 10, and the number of ring atoms of the thienyl group is 5.

In the present disclosure, the “aryl group or aromatic group” refers to an aromatic hydrocarbon group derived by removing one hydrogen atom from an aromatic ring compound, and may be a monocyclic aryl group, a fused ring aryl group, or a polycyclic aryl group, and at least one ring of the polycyclic aryl group is an aromatic ring system. For example, “an aryl group having 6 to 40 ring atoms” refers to an aryl group containing 6 to 40 ring atoms, preferably an aryl group having 6 to 30 ring atoms, more preferably an aryl group having 6 to 18 ring atoms, particularly preferably an aryl group having 6 to 14 ring atoms. Suitable examples include, but are not limited to, phenyl, biphenyl, terphenyl, naphthyl, anthracenyl, phenanthrenyl, fluoranthenyl, triphenylene, pyrenyl, perylenyl, tetraphenyl, fluorenyl, perylene, acenaphthenyl, and the like.

In the present disclosure, “alkyl” may represent a chain alkyl group or a cyclic alkyl group, where the chain alkyl group includes a linear alkyl group and a branched alkyl group. The number of carbon atoms of the alkyl group may be 1 to 50, 1 to 30, 1 to 20, 1 to 10, or 1 to 6. A phrase containing the term, for example, “C1-9 alkyl” refers to an alkyl group containing 1 to 9 carbon atoms, which at each occurrence can be independently of each other C1 alkyl, C2 alkyl, C3 alkyl, C4 alkyl, C5 alkyl, C6 alkyl, C7 alkyl, C8 alkyl, or C9 alkyl. Non-limiting examples of alkyl groups include methyl, ethyl, n-propyl, isopropyl, n-butyl, sec-butyl, tert-butyl, isobutyl, 2-ethylbutyl, 3,3-dimethylbutyl, n-pentyl, isopentyl, neopentyl, tert-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-tert-butylcyclohexyl, n-heptyl. 1-methylheptyl, 2,2-dimethylheptyl, 2-ethylheptyl, 2-butylheptyl, n-octyl, tert-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl. 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-cicosyl, 2-ethyleicosyl, 2-butyleicosyl, 2-hexyleicosyl, 2-octyleicosyl, n-docosyl, n-docosyl, n-tricosyl, n-tetracosyl, n-pentacosyl, n-hexacosyl, n-heptacosyl, n-octadecosyl, n-nonacosyl, n-triacontyl, adamantane, and the like.

In the present disclosure, a single bond to which a substituent is connected penetrates the corresponding ring, indicating that the substituent can be connected to an optional position of the ring. For example, R in

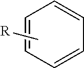

is connected to any substitutable site of the benzene ring, and

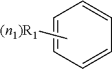

represents that a substituent R₁ is connected to n₁ substitutable sites in the benzene ring, that is, n₁ R₁ is connected to any substitutable site of the benzene ring one by one, and the R₁ connected at each site may be independently selected, and m₁ R₁ may be the same or different.

In the present disclosure, “amino” refers to a group having structural features of formula —NH₂; “cyano” refers to a group having the structural characteristics of the formula —C≡N; “nitro” refers to a group having structural features of formula —NO₂; “hydroxyl” refers to a group having the structural characteristics of the formula —OH; “halogen group” refers to —F, —Cl, —Br, or —I; “keto” refers to a group having the structural feature

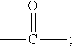

“carboxyl” refers to —COOH.

In the present disclosure, a “combination of a plurality of groups” means that a substituent attached at a single site on a ring is a combination of a plurality of recited groups, and the combination of a plurality of recited groups means that a hydrogen atom on at least one group is substituted with another group. By way of example: haloalkyl is a combination of an alkyl group and a halogen group, for example, —(CH₂)ₙBr; —NHR′ is a combination of an amino group and an R′ group, the R′ group being a designation given for convenience of description, which specifically refers to any one of the various groups listed; —COOH is a combination of a keto group and a hydroxyl group.

In the present disclosure, two substituents connected to two adjacent ring atoms on a ring are defined as adjacent substituents, and “two adjacent substituents are bonded to form a ring” means that adjacent substituents are bonded to each other so that adjacent substituents and two adjacent ring atoms together form a ring.

The technical solutions of the present disclosure are as follows.

In a first aspect, an embodiment of the present disclosure provides a composite material including a quantum dot and a ligand bound to a surface of the quantum dot. The ligand is an anthracene compound, and the anthracene compound includes at least one of anthraquinone, anthranol, anthrone, an anthraquinone derivative, an anthranol derivative, and an anthrone derivative.

The structural formula of anthraquinone is as follows:

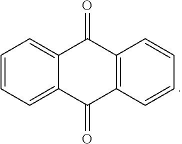 [SMILES: O=C1c2ccccc2C(=O)c2ccccc21]

anthranol include, but are not limited to, the following compound:

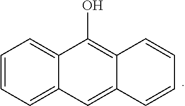 [SMILES: Oc1c2ccccc2cc2ccccc12]

Anthrone include, but are not limited to, the following compounds:

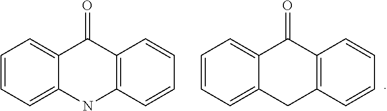

The anthraquinone derivative, the anthranol derivative, and the anthrone derivative are compounds in which hydrogen atoms in ring atoms of anthraquinone, anthranol, and anthrone are substituted, respectively.

It can be seen that anthraquinone, anthranol, anthrone and their respective derivatives all have large π-conjugated skeleton structures, which makes the composite material have excellent electrical conductivity. Using the composite material to prepare light-emitting layers of light-emitting devices is helpful to charge transport and improve the performance of devices. In addition, in the ligands provided by the present disclosure, anthraquinone, anthrone, and their corresponding derivatives all have at least C═O in their structures, and anthranol and its derivatives thereof have at least-OH in their structures. During the preparation process of quantum dot materials, anions in cation sources such as cadmium acetate, cadmium oxalate and cadmium carbonate will inevitably remain in the solution. C═O and —OH belong to strong adsorption groups, which have stronger adsorption capacity compared with impurity ions such as acetate, so that the ligand is more easily adsorbed on a surface of a quantum dot than the impurity ions, and the defects on the surface of the quantum dot are avoided from being filled by the impurity ions. In the composite material, since a ligand layer with high conductivity is formed on the surface of the quantum dot, the conductivity of the composite material is further improved.

In some embodiments of the present disclosure, the anthracene compound includes at least one of compounds having the structure shown in any one of formulas (1) to (3):

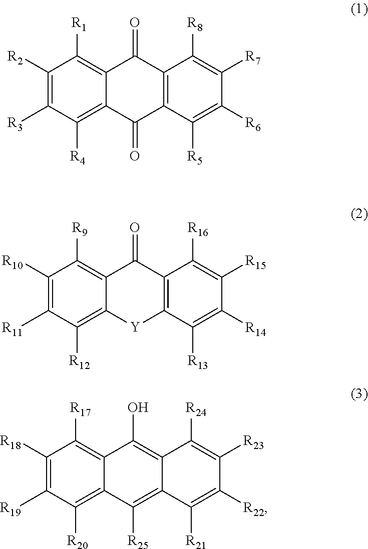

where Y is selected from CR₂₆R₂₇ or NR₂₈.

Among them, R₁ to R₂₈ are independently selected from any one of hydrogen, deuterium, alkyl, aryl, keto, cyano, hydroxyl, nitro, amino and halogen groups; or,
R₁ to R₂₈ are independently selected from a combination of a plurality of groups among hydrogen, deuterium, alkyl, aryl, keto, cyano, hydroxyl, nitro, amino and halogen groups; or,
R₁ to R₂₈ are independently selected from one or more of the above groups and two adjacent substituents of R₁ to R₂₈ are bonded to form a ring.

Hereinafter, the composite material will be described in detail in combination with the above three structural formulas.

In some embodiments of the present disclosure, the anthracene compound includes a compound having the structure represented by Formula (1):

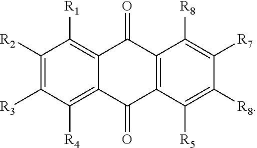

Among the above series of groups (hydrogen, deuterium, alkyl, aryl, keto, cyano, hydroxyl, nitro, amino and halogen groups), carboxyl, amino, halogen or haloalkyl is set as an active group, and the active group has a stronger adsorption capacity. In some embodiments, at least one of R₁ to R₈ is selected from the active groups, thus contributing to better adsorption of the ligand on the surface of the quantum dot. Further, when a plurality of substituents in R₁ to R₈ are selected from the active groups, the ligand has more coordination sites, which helps to enhance the connection between the ligand and the surface of the quantum dot, and inhibit the impurity ions from filling the defects on the surface of the quantum dot.

In addition, in the compound having the structure represented by the formula (1), a pair of carbonyl groups are connected to two sites at para positions on the host skeleton structure (i.e., anthracene ring). Since the host skeleton structure is a planar structure, the two carbonyl groups are opposite to each other. In this way, when the composite material is used to prepare the quantum dot light-emitting diode 100, one carbonyl group is connected to the quantum dot, and the other carbonyl group located at the para position may modify the defect of the electron transport layer, thereby effectively modifying the light emitting layer 20 and the electron transport layer 30 at the same time. Further, when a plurality of substituents in R₁ to R₈ are selected from the active groups, the distribution of the plurality of active groups on the ring is designed as follows: at least one of R₁, R₂, R₇ and R₈ is selected from the active groups, and at least one of R₃ to R₆ is selected from the active groups. As described above, the composite material not only has more sites capable of connecting to the quantum dot, but also has more sites for modifying the electron transport layer 30, thereby further improving the repair effect of the light-emitting layer 20 and the electron transport layer 30.

In some embodiments, at least one of R₁-R₈ is selected from hydrogen or deuterium. Due to the small molecular volume of the ligand, it may avoid affecting the conductivity of the composite material.

In addition, in some embodiments, the number of carbon atoms in the alkyl is less than or equal to 20, so that the molecular volume of the ligand is small, and thus it is possible to avoid affecting the conductivity of the composite material. In other embodiments, the number of ring atoms in the aryl is less than or equal to 60, so that the molecular volume of the ligand is small, and thus it is possible to avoid affecting the conductivity of the composite material.

In some embodiments of the present disclosure, the anthracene compounds includes a compound having the structure represented by Formula (2):

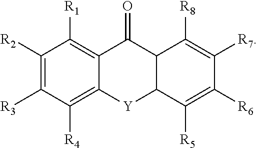

When Y is NR₂₈, the anthrone derivative is acridone and derivatives thereof. In some embodiments, at least one of R₉ to R₁₆ and R₂₈ is selected from the active groups, thus contributing to better adsorption of the ligand on the surface of the quantum dot. Further, when a plurality of substituents in R₉ to R₁₆ and R₂₈ are selected from the active groups, the ligand has more coordination sites, which helps to enhance the connection between the ligand and the surface of the quantum dot, and inhibit the impurity ions from filling the defects on the surface of the quantum dot.

When Y is CR₂₆R₂₇, the anthrone derivative is anthrone and derivatives thereof. In some embodiments, at least one of R₉ to R₁₆ and R₂₆ to R₂₇ is selected from the active groups, thus contributing to better adsorption of the ligand on the surface of the quantum dot. Further, when a plurality of substituents in R₉ to R₁₆ and R₂₆ to R₂₇ are selected from the active groups, the ligand has more coordination sites, which helps to enhance the connection between the ligand and the surface of the quantum dot, and inhibit the impurity ions from filling the defects on the surface of the quantum dot.

In addition, in some embodiments, when Y is selected from CR₂₆R₂₇, at least one of R₁₁-R₁₄ and R₂₆-R₂₇ is selected from the active groups. In this way, when the composite material is used to prepare the quantum dot light-emitting diode 100, one of the carbonyl group and the active groups may be connected to the quantum dot, and the other may modify the defect of the electron transport layer, thereby effectively modifying the light-emitting layer 20 and the electron transport layer 30 at the same time. In other embodiments, when Y is selected from NR₂₈, at least one of R₁₁ to R₁₄ and R₂₈ is selected from the active groups. In this way, when the composite material is used to prepare the quantum dot light-emitting diode 100, one of the carbonyl group and the active groups may be connected to the quantum dot, and the other may modify the defect of the electron transport layer, thereby effectively modifying the light-emitting layer 20 and the electron transport layer 30 at the same time.

In some embodiments, at least one of R₉ to R₁₆ is selected from hydrogen or deuterium, so that the molecular volume of the ligand is small, and thus it is possible to avoid affecting the conductivity of the composite material.

In addition, in some embodiments, the number of carbon atoms in the alkyl is less than or equal to 20, so that the molecular volume of the ligand is small, and thus it is possible to avoid affecting the conductivity of the composite material. In other embodiments, the number of ring atoms in the aryl is less than or equal to 60, so that the molecular volume of the ligand is small, and thus it is possible to avoid affecting the conductivity of the composite material.

In some embodiments of the present disclosure, the anthracene compound includes a compound having the structure represented by Formula (3):

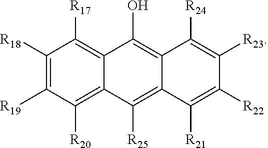

In some embodiments, at least one of R₁₇ to R₂₅ is selected from the active groups, thereby contributing to better adsorption of the ligand on the surface of the quantum dot. Further, when a plurality of substituents in R₁₇ to R₂₅ are selected from the active groups, the ligand has more coordination sites, which helps to enhance the connection between the ligand and the surface of the quantum dot, and inhibit the impurity ions from filling the defects on the surface of the quantum dot.

In addition, in some embodiments, at least one of R₁₉ to R₂₂ and R₂₅ includes the active group, so that when the composite material is used to prepare the quantum dot light-emitting diode 100, one of the hydroxyl group at the para position of R₂₅ and the active group is connected to the quantum dot, and the other may modify the defect of the electron transport layer, thereby effectively modifying the light-emitting layer 20 and the electron transport layer 30 at the same time.

In some embodiments, at least one of R₁₇ to R₂₅ is selected from hydrogen or deuterium, so that the molecular volume of the ligand is small, and thus it is possible to avoid affecting the conductivity of the composite material.

In addition, in some embodiments, the number of carbon atoms in the alkyl is less than or equal to 20, so that the molecular volume of the ligand is small, and thus it is possible to avoid affecting the conductivity of the composite material. In other embodiments, the number of ring atoms in the aryl is less than or equal to 60, so that the molecular volume of the ligand is small, and thus it is possible to avoid affecting the conductivity of the composite material.

In some specific embodiments, the anthracene compound includes at least one of compounds having the structure represented by any one of the following structural formulas (4) to (30):

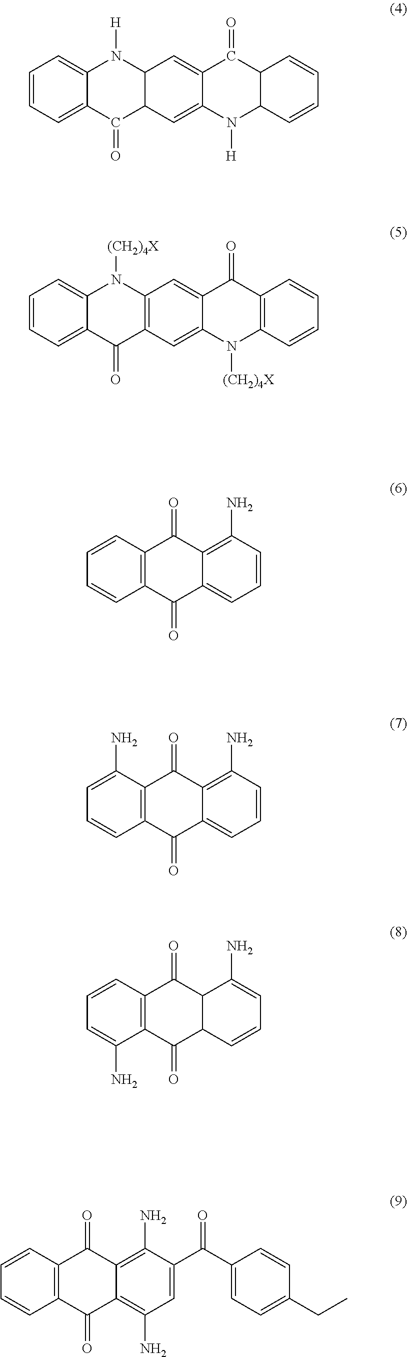

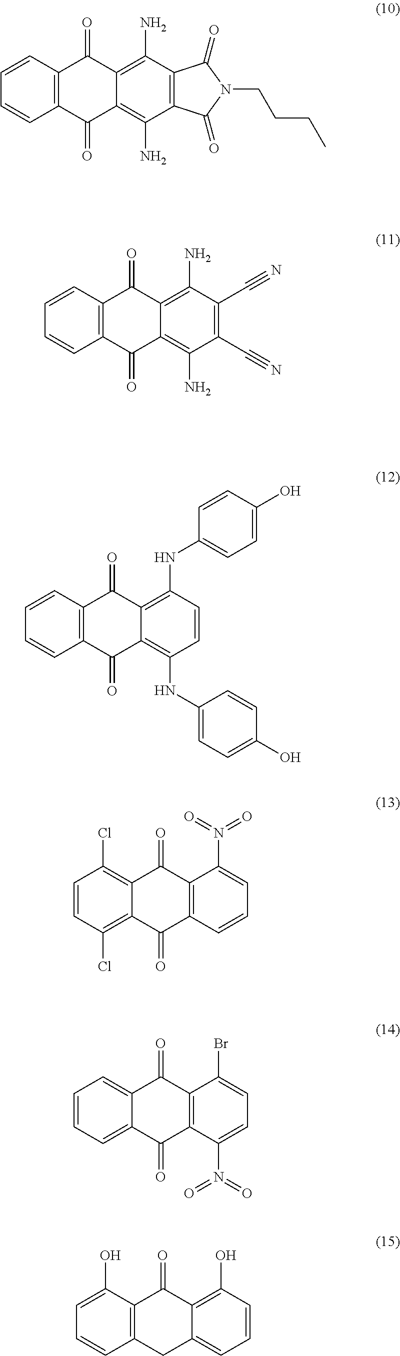

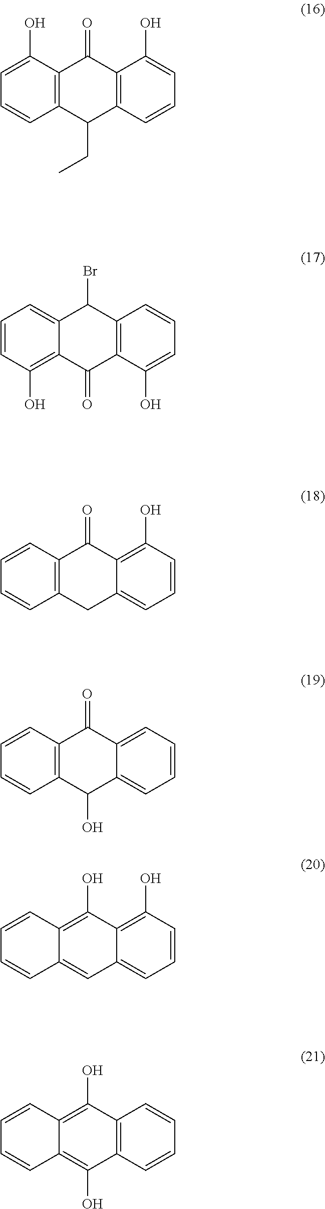

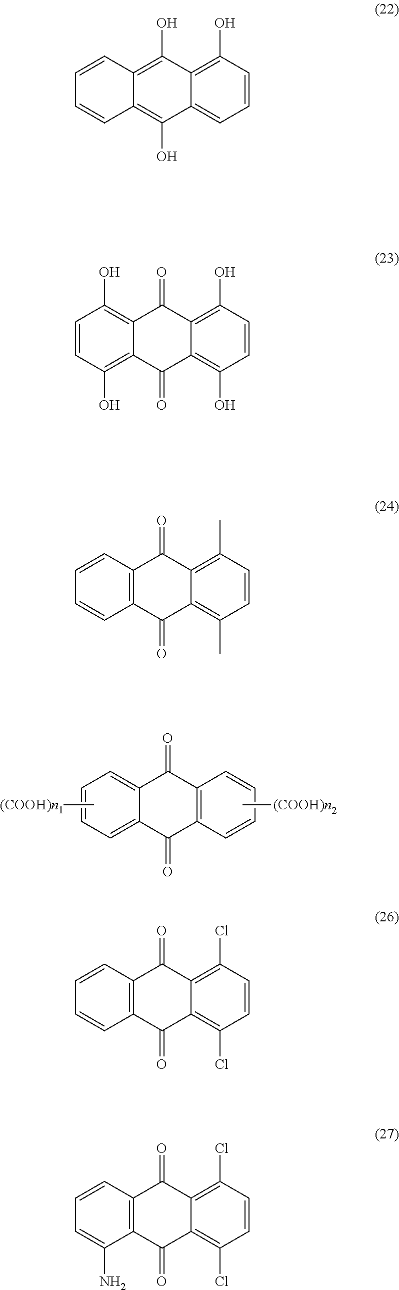

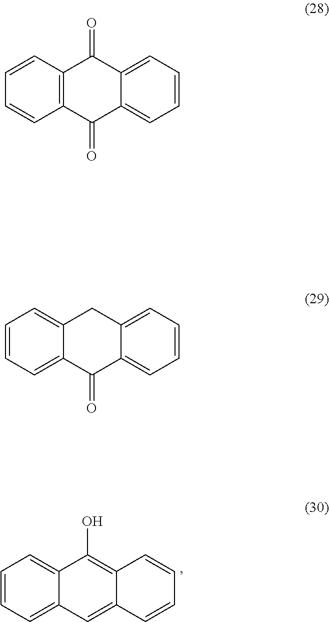

where n is a positive integer less than or equal to 20, X is Cl, Br or I, n₁ and n₂ are independently selected from 0, 1, 2, 3, or 4, and a sum of n₁ and n₂ is greater than or equal to 1. For example, n may be 1, 2, 3, 4, 5, 6, 7, 8, 9, 10, 11, 12, 13, 14, 15, 16, 17, 18, 19, or 20; and n₁ and n₂ may be 0, 1, 1, 1, 2, 2, 1, 2, respectively.

In some embodiments of the present disclosure, in the composite material, a molar ratio of the quantum dot and the ligand is 1:(1 to 10), for example, the molar ratio of the quantum dot and the ligand may be 1:1, 1:2, 1:3, 1:5, 1:6, 1:8, 1:10, a ratio value between any two of the above ratios, or the like. Further, in the composite material, the molar ratio of the quantum dot and the ligand is 1:(2 to 5), for example, 1:2, 1:3, 1:4, 1:5, etc., which helps to reduce the defects on the surface of the quantum dot and reduce the amount of the ligand used.

The quantum dot is selected from at least one of a single structure quantum dot and a core-shell structure quantum dot; the single structure quantum dot is selected from at least one of a group II-VI compound, a group IV-VI compound, a group III-V compound, and a group I-III-VI compound, the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb, the group I-III-VI compound is selected from one or more of CuInS₂, CuInSe₂, and AgInS₂; a core of the core-shell structure quantum dot is selected from any one of the single structure quantum dots, and a shell material of the core-shell structure quantum dot is selected from at least one of CdS, CdTe, CdSeTe, CdZnSe, CdZnS, CdSeS, ZnSe, ZnSeS, and ZnS.

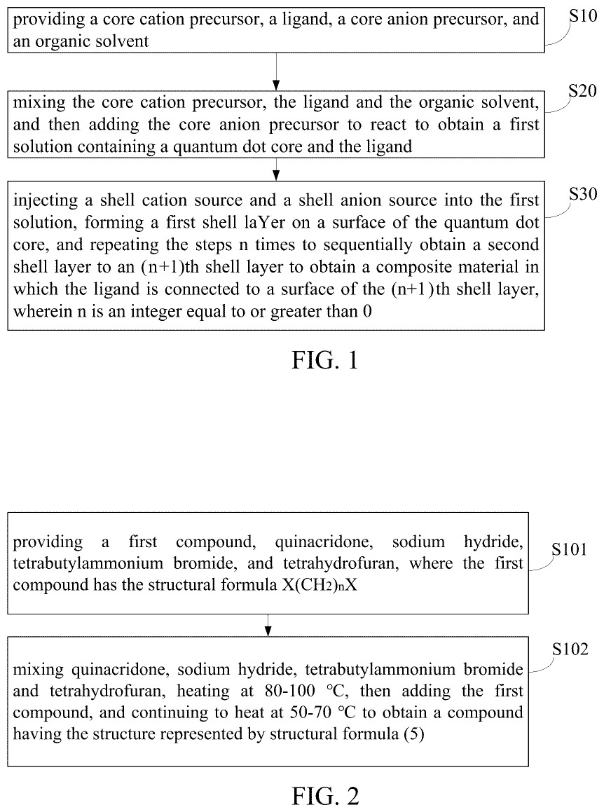

In a second aspect, the present disclosure also provides a method for preparing a composite material. Referring to FIG. 1, the method for preparing the composite material include:
step S10, providing a core cation precursor, a ligand, a core anion precursor, and an organic solvent;
step S20, mixing the core cation precursor, the ligand and the organic solvent, and then adding the core anion precursor to react to obtain a first solution containing a quantum dot core and the ligand; and,
step S30: injecting a shell cation source and a shell anion source into the first solution, forming a first shell layer on a surface of the quantum dot core, and repeating the steps n times to sequentially obtain a second shell layer to an n+1-th shell layer to obtain a composite material in which the ligand is connected to a surface of the n+1-th shell layer, wherein n is an integer equal to or greater than 0.

The ligand is an anthracene compound, and the anthracene compound includes at least one of anthraquinone, anthranol, anthrone, an anthraquinone derivative, an anthranol derivative, and an anthrone derivative.

In step S10, the core cation precursor includes at least one of a cadmium source, a zinc source, an indium source, a copper source, and a silver source.

The core anion precursor includes at least one of a selenium source, a sulfur source, a tellurium source, and a phosphorus source.

The shell cation source includes at least one of a cadmium source and a zinc source.

The shell anion source includes at least one of a selenium source, a sulfur source, a tellurium source, and a phosphorus source.

The organic solvent includes an organic compound having 10 to 22 carbon atoms, and the organic compound is selected from at least one of alkanes, olefins, halogenated hydrocarbons, aromatic hydrocarbons, ethers, amines, ketones, and esters. As an example, the organic solvent is at least one of tetradecene, pentadecene, tetradecane, pentadecane, hexadecane, heptadecane, octadecane, nonadecane, and paraffin oil.

In the process of preparing the composite material, adding the ligand may effectively increase the physical distance between the quantum dots, avoid the agglomeration of particles in the solution, increase the solubility of the quantum dots, and thus affect the improvement of the storage stability of the solution. After forming a quantum dot with n+1 shell layers, the ligand is attached to the surface of the (n+1)th shell layer.

In step S20, a temperature of reacting is 180° C. to 320° C. Specifically, step S20 may include mixing the core cation precursor, the ligand, and the organic solvent, raising the temperature to 180° C. to 320° C., adding the core anion precursor, and reacting to obtain the first solution containing the quantum dot core. The temperature of reacting may be 180° C., 200° C., 210° C., 220° C., 250° C., 260° C., 280° C., 300° C., 310° C., 320°° C., a value between any two of the above-mentioned temperatures, or the like.

Further, in step S20, a time of reacting is 1 to 2 hours. That is, the core cation precursor, the ligand, and the organic solvent are mixed, the core anion precursor is added, and the reaction is performed for 1 to 2 hours to obtain the first solution containing the quantum dot core to obtain the composite material. Specifically, the time of reacting may be 1 h, 1.1 h, 1.5 h, 1.6 h, 1.8 h, 1.9 h, 2 h, a value between any two of the above values, or the like.

Further, in some embodiments, the step S30 is performed at 240-320° C. That is, step S30 may specifically include: injecting a first shell cation source and a first shell anion source into the first solution at 240-320° C., and forming a first shell layer on the surface of the quantum dot core; then injecting a second shell layer cation source and a second shell layer anion source at 240-320° C. to obtain a second shell layer; repeating the step of preparing the shell layer at 240-320° C. until the (n+1)th shell layer is obtained, and the ligand is connected to the surface of the (n+1)th shell layer to obtain the composite material. Specifically, the reaction temperature for preparing the shell layer may be 240° C., 250° C., 260° C., 280° C., 300° C., 310° C., 320° C., a value between any two of the above-mentioned temperatures, or the like. Further, in this step, the reaction time is 1 to 20 min, for example, 1 min, 2 min, 5 min, 8 min, 10 min, 15 min, 18 min, 20 min, a value between any two of the above-mentioned values, or the like.

In a specific embodiment, the quantum dot is a CdZnSeS/ZnSe/ZnS quantum dot, that is, the composite material has two shells. In an embodiment, the core cation precursor includes a cadmium source and a zinc source, and the core anion precursor includes a first selenium source and a first sulfur source. The shell cation source is a zinc source, and the shell anion source includes a second selenium source and a second zinc source. Specifically, the cadmium source includes at least one of cadmium powder, cadmium oxide, cadmium chloride, cadmium oxalate, cadmium acetate, cadmium carbonate, cadmium stearate, cadmium acetylacetonate, and cadmium tetradecanate. The zinc source includes at least one of zinc powder, zinc oxide, zinc chloride, zinc oxalate, zinc acetate, zinc carbonate, zinc stearate, zinc acetylacetonate, zinc tetradecanoate, and zinc undecylenate. The first selenium source and the second selenium source are independently selected from at least one of inorganic selenium, an organophosphorus complex of selenium, an organic selenium compound, and an organic selenol compound. As an example, the selenium source includes at least one of selenium powder, selenium-pentadecene solution, selenium dioxide, trioctylphosphine selenide, tributylphosphine selenide, selenol, diselenide, selenoether, selenoate, selenoamide, and selenazole. The first sulfur source and the second sulfur source are independently selected from at least one of inorganic sulfur, an organophosphorus complex of sulfur, an organic sulfur compound, and an organic thiol compound. As an example, the sulfur source includes at least one of sulfur powder, sulfur-pentadecene solution, n-octylamine solution having sulfur, trioctylphosphine sulfide, tributylphosphine sulfide, and 1-octanethiol.

Based on a specific embodiment of the CdZnSeS/ZnSe/ZnS quantum dot, in step S20 of the present embodiment, a ratio of the sum of the molar amounts of cadmium ions in the cadmium source and zinc ions in the zinc source to the molar amount of the ligand is 1:(1 to 10), for example, the ratio of the sum of the molar amounts of cadmium ions in the cadmium source and zinc ions in the zinc source to the molar amount of the ligand may be 1:1, 1:2, 1:3, 1:4, 1:5, 1:6, 1:7, 1:8, 1:9, 1:10, or the like. A molar ratio of zinc ions in the zinc source to cadmium ions in the cadmium source is (18-20):1, for example, the molar ratio may be 18:1, 18.5:1, 18.6:1, 18.8:1, 19:1, 19.2:1, 19.5:1, 19.8:1, 20:1, etc. In step S30a, a molar ratio of the sum of the molar amounts of the selenium ions in the first selenium source and the sulfur ions in the first sulfur source to the cadmium ions in the cadmium source is (1 to 8):1, for example, the molar ratio may be 1:1, 2:1, 3:1, 4:1, 5:1, 6:1, 7:1, 8:1, or the like. A molar ratio of selenium ions in the second selenium source to cadmium ions in the cadmium source is (0.5-2):1, for example, the molar ratio may be 0.5:1, 0.6:1, 0.8:1, 1:1, 1.2:1, 1.5:1, 1.8:1, 2:1, etc. A molar ratio of sulfur ions in the second sulfur source to cadmium ions in the cadmium source is (6 to 10):1, for example, the molar ratio may be 6:1, 7:1, 8:1, 9:1, 10:1, or the like.

In another specific embodiment, the quantum dot is an InP/ZnSe/ZnS quantum dot, and the method for preparing the composite material is as follow. 0.2 mmol of indium chloride, 1 mmol of zinc acetate, 1 mmol of the ligand and 100 ml of 1-octadecene are mixed. The temperature is raised to 280° C. under an inert gas atmosphere, then 0.15 mmol of tris(trimethylsilyl)phosphine is injected to react for 60 minutes to obtain a solution. After the reaction is finished, the temperature is raised to 300° C. 0.2 mmol of tributylphosphine selenide is added to the solution to continue react for 20 minutes. Then, 0.1 mmol of octanethiol and 2 mmol of zinc oleate are added to continue react for 30 minutes to obtain a product. The composite material is obtained by using n-heptane and ethanol to precipitate and purify the product.

Further, in some embodiments, the ligand includes a compound having the structure represented by structural formula (5).

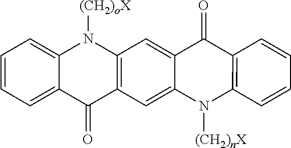

Referring to FIG. 2, in an embodiment, prior to step S10, the method further includes:
step S101, providing a first compound, quinacridone, sodium hydride, tetrabutylammonium bromide, and tetrahydrofuran, where the first compound has the structural formula X(CH₂)ₙX, with X being said Cl, Br or I;
step S102, mixing quinacridone, sodium hydride, tetrabutylammonium bromide and tetrahydrofuran, heating at 80-100° C., then adding the first compound, and continuing to heat at 50-70° C. to obtain a compound having the structure represented by structural formula (5).

A molar ratio of quinacridone, the first compound, sodium hydride, and tetrabutylammonium bromide is 1:(1-5):(5-8):(1-3). Specifically, 1 to 5 mol of the first compound is added per 1 mol of quinacridone, and as an example, a molar quantity of the first compound added may be 1 mol, 2 mol, 3 mol, 4 mol, 5 mol, a value between any two values listed above, and the like; 5-8 sodium hydride is added per 1 mol of quinacridone, and as an example, a molar quantity of sodium hydride added may be 5 mol, 6 mol, 7 mol, 8 mol, a value between any two values listed above, and the like; 1 to 5 mol of tetrabutylammonium bromide is added per 1 mol of quinacridone, and as an example, a molar quantity of tetrabutylammonium bromide added may be 1 mol, 2 mol, 2.5 mol, 3 mol, a value between any two values listed above, and the like.

In step S102, a time of heating at 80 to 100° C. is 1 to 2 h, for example, 1 h, 1.2 h, 1.5 h, 2 h, a value between any two values listed above, or the like; a time of heating at 50-70° C. is 12-24 h, for example, between 12 h, 15 h, 20 h, 24 h, a value between any two values mentioned above, and the like.

After the compound having the structure represented by the structural formula (5) is prepared in step S102, the compound may be used as a ligand directly in step S10, or may be mixed with another anthracene compound and used together as ligands in step S10.

In other embodiments, the ligand includes a compound having the structure of structural formula (25).

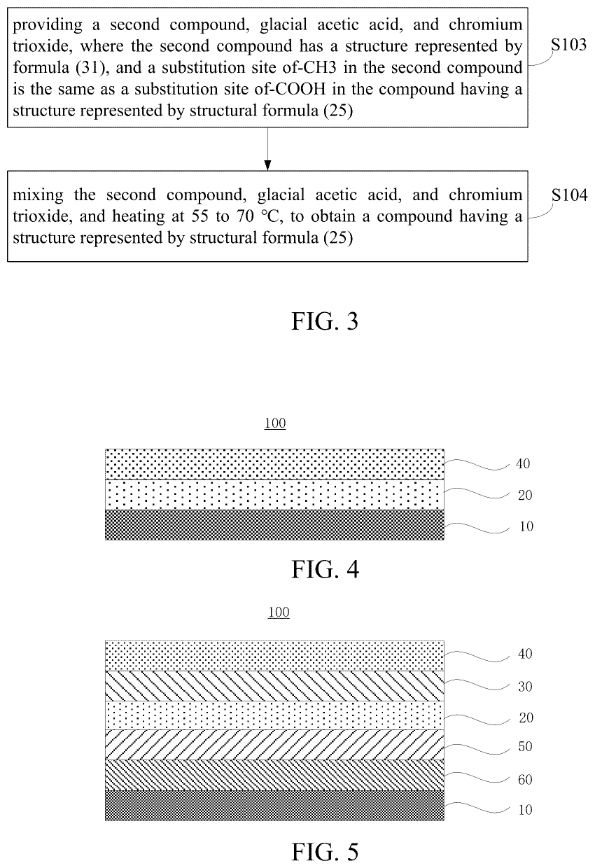

Referring to FIG. 3, in this embodiment, prior to step S10, the method further includes:
Step S103, providing a second compound, glacial acetic acid, and chromium trioxide, where the second compound has a structure represented by formula (31), and a substitution site of —CH3 in the second compound is the same as a substitution site of —COOH in the compound having a structure represented by structural formula (25);
Step S104, mixing the second compound, glacial acetic acid, and chromium trioxide, and heating at 55 to 70° C., to obtain a compound having a structure represented by structural formula (25).

After the compound having the structure represented by the structural formula (25) is prepared in step S104, the compound may be used as a ligand directly in step S10, or may be mixed with another anthracene compound and used together as ligands in step S10.

In a third aspect, referring to FIG. 4, the present disclosure also proposes a quantum dot light-emitting diode 100, an anode 10, a light-emitting layer 20, and a cathode 40 which are stacked, wherein a material of the light-emitting layer 20 includes a composite material. The composite material includes a composite material as described above, or the composite material is prepared by a method for preparing a composite material as described above.

The light-emitting layer 20 contains the composite material, and a thickness of the light-emitting layer 20 may be 20 to 50 nm, for example, 20 to 30 nm, 25 to 32 nm, 30 to 40 nm, 35 to 50 nm, or the like.

The materials of the cathode 40 and anode 10 may be any of those known in the art. The material of the anode 10 and the cathode 40 may be, for example, a metal electrode, a carbon-silicon material electrode, a metal oxide electrode, or a composite electrode, a material of the metal electrode is selected from at least one of Ag, Al, Mg, Au, Cu, Mo, Pt, Ca, and Ba, a material of the carbon-silicon material electrode is selected from at least one of silicon, graphite, carbon nanotubes, graphene, and carbon fiber, a material of the metal oxide electrode is selected from at least one of indium doped tin oxide, fluorine doped tin oxide, antimony doped tin oxide, aluminum doped zinc oxide, gallium doped zinc oxide, indium doped zinc oxide, magnesium doped zinc oxide and aluminum doped magnesium oxide, and the composite electrode is selected from at least one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS and ZnS/Al/ZnS. A thickness of the cathode 40 and the anode 10 may be 10 to 1000 nm, for example, 10 to 30 nm, 25 to 50 nm, 40 to 80 nm, 75 to 100 nm, 90 to 200 nm, 150 to 300 nm, 200 to 600 nm, 500 to 1000 nm, and the like.

In the quantum dot light-emitting diode 100 of the present disclosure, since the ligand bound to the surface of the quantum dot in the composite material has a large π-conjugated skeleton structure, the light-emitting layer 20 has excellent conductivity. At the same time, the ligand has at least a strong adsorption group such as C═O or —OH, so that the ligand is more easily adsorbed on the surface of the quantum dot than the impurity ion, thereby preventing the impurity ion from filling the defect on the surface of the quantum dot, forming the ligand layer with high conductivity on the surface of the quantum dot, further improving the conductivity of the light-emitting layer 20, and improving the luminous efficiency and life of the quantum dot light-emitting diode 100.

As can be understood, with further reference to FIG. 5, the quantum dot light-emitting diode 100 may also be added with some functional layers conventionally used for the quantum dot light-emitting diode 100 to help improve the performance of the light-emitting diode, such as a hole transport layer 50, a hole injection layer 60, an electron transport layer 30, and the like.

A material of the hole transport layer 50 may be selected from organic materials having hole transport capabilities, including but not limited to one or more of poly (9,9-dioctylfluorene-CO—N-(4-butylphenyl) diphenylamine) (TFB), polyvinylcarbazole (PVK), poly (N,N′-bis (4-butylphenyl)-N,N′-bis (phenyl) benzidine) (poly-TPD), poly (9,9-dioctylfluorene-co-bis-N,N-phenyl-1,4-phenylenediamine) (PFB), 4′-tris(carbazol-9-yl) triphenylamine (TCATA), 4,4′-bis(9-carbazole) biphenyl (CBP), N,N′-diphenyl-N,N′-bis(3-methylphenyl)-1,1′-biphenyl-4,4′-diamine (TPD), N,N′-diphenyl-N,N′-(1-naphthyl)-1,1′-biphenyl-4,4′-diamine (NPB), poly (3,4-ethylenedioxythiophene)-poly (styrenesulfonic acid) (PEDOT: PSS). Spiro-NPB, Spiro-TPD, doped graphene, undoped graphene, and C60. A material of the hole transport layer 50 may also be selected from inorganic materials having hole transport capabilities, including, but not limited to, one or more of doped or undoped NiO, MoO₃, WO₃, V₂O₅, P-type gallium nitride, CrO₃, and CuO. A thickness of the hole transport layer 50 may be 20-100 nm, for example, 20-30 nm, 25-32 nm, 30-40 nm, 35-50 nm, 45-80 nm, 75-100 nm, or the like.

A material of the hole injection layer 60 may include, but is not limited to, at least one of PEDOT: PSS (poly (3,4-ethylenedioxythiophene)-polystyrenesulfonic acid), CuPc, TiOPc (titanium phthalocyanine oxide), m-MTDATA (CAS: 124729-98-2), 2-TNATA (4,4′, 4″-tris(2-naphthylphenylaminotriphenylamine)), a transition metal oxide, and a transition metal chalcogenide. The transition metal oxide includes at least one of NiOₓ, MoOₓ, WOₓ, CrOₓ, CuO; the metal chalcogenide compound includes at least one of MoSₓ, MoSeₓ, WSₓ, WSeₓ, and CuS. Among them, a value of x in each compound may be determined according to the valence of the atoms in the compound. A thickness of the hole injection layer 60 may be 20-50 nm, for example, 20-30 nm, 25-32 nm, 30-40 nm, 35-50 nm, or the like.

A material of the electron transport layer 30 includes, but is not limited to, a metal-doped or non-doped metal oxide. The metal oxide includes at least one of ZnO, NiO, W₂O₃, Mo₂O₃, TiO₂, SnO, ZrO₂, Ta₂O₃, Ga₂O₃, SiO₂, Al₂O₃, CaO, HfO₂, SrTiO₃, BaTiO₃, and MgTiO₃, and a doping metal element is selected from Mg, Ca, Li, Ga, Al, Co, and Mn. A thickness of the electron transport layer 30 may be 30 to 50 nm, for example, 30 to 35 nm, 32 to 40 nm, 35 to 50 nm, or the like.

It is understood that a material of each layer of the quantum dot light-emitting diode 100 may be adjusted according to the light emission requirements of the quantum dot light-emitting diode 100.

It can be understood that the quantum dot light emitting diode 100 may be an upright light emitting diode or an inverted light emitting diode.

An embodiment of the present disclosure also provides a method for preparing a quantum dot light emitting diode 100, including the following steps.

In step S11, a substrate having an anode 10 is provided.

In step S12, the composite material is disposed on the anode 10 to form a light emitting layer 20.

In step S13, a cathode 40 on the light-emitting layer 20 is formed.

It can be understood that when the quantum dot light emitting diode 100 further includes a hole injection layer 60, a hole transport layer 50, and an electron transport layer 30, the method for preparing the quantum dot light emitting diode 100 includes the following steps.

In step S11a, the substrate with the anode 10 is provided, and the hole injection layer 60 and the hole transport layer 50 are formed by stacking on the anode 10 in turn.

In step S12, the composite material is disposed on the hole transport layer 50 to form the light emitting layer 20.

In step S13a, the electron transport layer 30 and the cathode 40 are sequentially formed on the light-emitting layer 20.

Among the two methods for preparing the light-emitting diodes, the methods for preparing the anode 10, the hole transport layer 50, the light-emitting layer 20, the electron transport layer 30, an interface modification layer, the cathode 40, and the hole transport layer 50 may be realized by conventional techniques in the art, such as chemical methods or physical methods. Among them, chemical methods include chemical vapor deposition, continuous ion layer adsorption and reaction, anodic oxidation, electrolytic deposition and coprecipitation. The physical method includes physical coating method and solution method. Among them, the physical coating method includes: a thermal evaporation coating method, an electron beam evaporation coating method, a magnetron sputtering method, a multi-arc ion coating method, a physical vapor deposition method, an atomic layer deposition method, a pulsed laser deposition method, etc.; the solution method may be a spin coating method, a printing method, an inkjet printing method, a scraping method, a printing method, a dipping and pulling method, a soaking method, a spraying method, a rolling coating method, a casting method, a slit coating method and a strip coating method.

Materials of the anode 10, the hole injection layer 60, the hole transport layer 50, the light emitting layer 20, the electron transport layer 30, and the cathode 40 are described above, and will not be described herein.

Hereinafter, technical solutions and technical effects of the present disclosure will be described in detail with reference to specific examples, comparative examples, and experimental examples, and the following examples are merely partial examples of the present disclosure, and do not specifically limit the present disclosure.

### EXAMPLE 1

In a composite material provided in this embodiment, the ligand is quinacridone (CAS: 1047-16-1) and has the following structural formula.

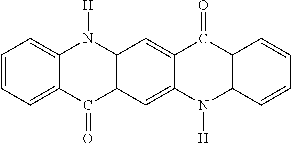 [SMILES: O=C1C2=CC3Nc4ccccc4C(=O)C3C=C2NC2C=CC=CC12]

The method for preparing the composite material is as follows.

0.4 mmol of cadmium oxide, 8 mmol of zinc acetate, 8 mmol of quinacridone and 200 ml of 1-octadecene were mixed. The temperature was raised to 300° C. under an inert gas atmosphere, and 0.4 mmol of trioctylphosphine selenide and 0.2 mmol of trioctylphosphine sulfide were injected to carry out a reaction. After the reaction was completed, the temperature was lowered to 280° C., 0.22 mmol of trioctylphosphine selenide was added, and the reaction was continued. Finally, 3 mmol of trioctylphosphine sulfide was added to continue react to obtain a product. The product was precipitated and purified using n-heptane and ethanol to obtain CdZnSeS/ZnSe/ZnS quantum dot composites.

The method for preparing a quantum dot light emitting diode includes the following steps.

In step S1, a substrate with an ITO anode of 100 nm thickness was provided, and a layer of PEDOT: PSS was deposited on the substrate to obtain a hole injection layer having a thickness of 25 nm.

In step S2, a layer of PVK was deposited on the hole injection layer to obtain a hole transport layer having a thickness of 25 nm.

In step S3, a concentration of the solution containing the composite material and n-heptane was 20 mg/mL, and the solution containing the composite material and n-heptane was deposited on the hole transport layer to obtain a light-emitting layer having a thickness of 30 nm.

In step S4, a solution containing ZnO was provided, the concentration of the solution containing ZnO was 30 mg/ml, and the solution containing ZnO was deposited on the light-emitting layer to obtain an electron transport layer having a thickness of 40 nm.

In step S5, Al was deposited on the electron transport layer to obtain a cathode having a thickness of 100 nm

### EXAMPLE 2

The scheme of this Example is similar to that of Example 1 except that the ligand is a quinacridone derivative with the following structural formula.

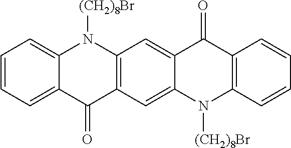

A method of preparing the ligand is as follows.

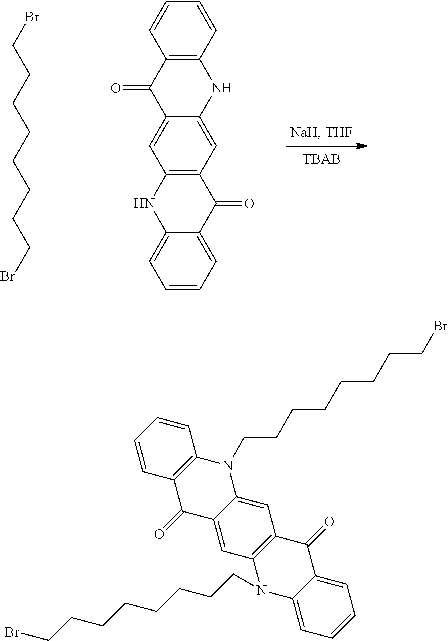 [SMILES: BrCCCCCCCCBr ; O=c1c2ccccc2[nH]c2cc3c(=O)c4ccccc4[nH]c3cc12 ; O=c1c2ccccc2n(CCCCCCCCBr)c2cc3c(=O)c4ccccc4n(CCCCCCCCBr)c3cc12]

Sodium hydride (1.43 g, 50 mmol) and tetrabutylammonium bromide (TBAB) (2.57 g, 8 mmol) were added to a solution containing quinacridone (2.48 g, 8 mmol) and tetrahydrofuran (THF, 50 mL) to obtain a mixture. The mixture was heated to reflux at 80° C. for 1 h, then 1, 8-dibromooctane (10.88 g, 40 mmol) was added under nitrogen to obtain a reaction mixture. The reaction mixture was heated to reflux at 60° C. overnight, then methanol (30 mL) was slowly added to decompose excess sodium hydride, and finally distilled with solvent to give a crude solid. The crude solid was subjected to chromatography on a silica gel column to further purify to give 3.15 g of the title compound-the quinacridone derivative. The silica gel column used chloroform as eluent.

The product was identified, NMR data of the product was: ¹H NMR (400 MHz, CDCl₃) 8.68 (s, 2H), 8.52 (d, J=8.0 Hz, 2H), 7.70 (t, J=7.8 Hz, 2H), 7.45 (d, J=8.8 Hz, 2H), 7.23 (t, J=7.4 Hz, 2H), 4.47 (s, 4H), 3.42 (s, 4H), 1.98 (s, 4H), 1.88 (s, 4H), 1.62 (s, 4H), 1.48 (s, 12H). The identification results showed that the product had the above structure and was the target compound-the quinacridone derivative.

### EXAMPLE 3

The scheme of this Example is similar to that of Example 1 except that the ligand is 1-aminoanthraquinone, the CAS number of the ligand is 82-45-1, and the ligand has the following structural formula.

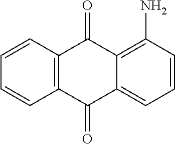 [SMILES: Nc1cccc2c1C(=O)c1ccccc1C2=O]

### EXAMPLE 4

The scheme of this Example is similar to that of Example 1 except that the ligand is 1,8-diamino-anthraquinon, the CAS number of the ligand is 129-42-0, and the ligand has the following structural formula.

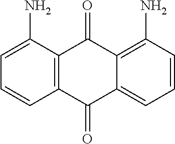 [SMILES: Nc1cccc2c1C(=O)c1c(N)cccc1C2=O]

### EXAMPLE 5

The scheme of this Example is similar to that of Example 1 except that the ligand is 9,10-Anthracenedione, 1,5-diamino-4a,9a-dihydro, the CAS number of the ligand is 1422011-39-9, and the ligand has the following structural formula.

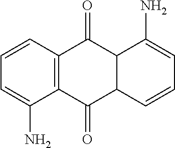 [SMILES: NC1=CC=CC2C(=O)c3c(N)cccc3C(=O)C12]

### EXAMPLE 6

The scheme of this Example is similar to that of Example 1 except that the ligand is 9,10-Anthracenedione, 1,4-diamino-2-(4-ethylbenzoyl)-, the CAS number of the ligand is 89868-41-7, and the ligand has the following structural formula.

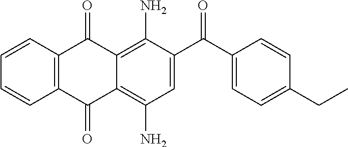 [SMILES: CCc1ccc(C(=O)c2cc(N)c3c(c2N)C(=O)c2ccccc2C3=O)cc1]

### EXAMPLE 7

The scheme of this Example is similar to that of Example 1 except that the ligand is 4,11-diamino-2-butyl-1H-naphth[2,3-f]isoindole-1,3,5,10(2H)-tetrone, the CAS number of the ligand is 3176-88-3, and the ligand has the following structural formula.

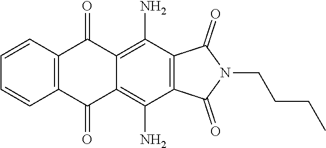 [SMILES: CCCCn1c(=O)c2c(N)c3c(=O)c4ccccc4c(=O)c3c(N)c2c1=O]

### EXAMPLE 8

The scheme of this Example is similar to that of Example 1 except that the ligand is 1,4-Diamino-2,3-dicyanoanthraquinone, the CAS number of the ligand is 81-41-4, and the ligand has the following structural formula.

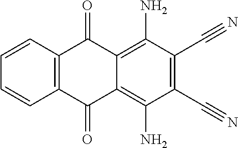

### EXAMPLE 9

The scheme of this Example is similar to that of Example 1 except that the ligand is 9,10-Anthracenedione, 1,4-bis[(4-hydroxyphenyl)amino]-, the CAS number of the ligand is 15939-83-0, and the ligand has the following structural formula.

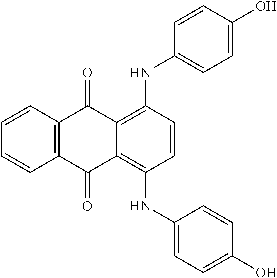 [SMILES: O=C1c2ccccc2C(=O)c2c(Nc3ccc(O)cc3)ccc(Nc3ccc(O)cc3)c21]

### EXAMPLE 10

The scheme of this Example is similar to that of Example 1 except that the ligand is 1,4-dichloro-5-nitroanthraquinone, the CAS number of the ligand is 3223-90-3, and the ligand has the following structural formula.

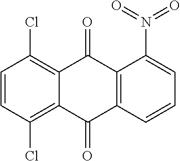 [SMILES: O=C1c2cccc([N+](=O)[O-])c2C(=O)c2c(Cl)ccc(Cl)c21]

### EXAMPLE 11

The scheme of this Example is similar to that of Example 1 except that the ligand is 1-bromo-4-nitro-anthraquinone, the CAS number of the ligand is 780038-86-0, and the ligand has the following structural formula.

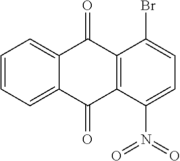 [SMILES: O=C1c2ccccc2C(=O)c2c([N+](=O)[O-])ccc(Br)c21]

### EXAMPLE 12

The scheme of this Example is similar to that of Example 1 except that the ligand is dithranol, the CAS number of the ligand is 1143-38-0, and the ligand has the following structural formula.

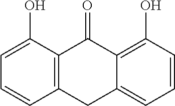 [SMILES: O=C1c2c(O)cccc2Cc2cccc(O)c21]

### EXAMPLE 13

The scheme of this Example is similar to that of Example 1 except that the ligand is 10-ethyldithranol, the CAS number of the ligand is 104608-82-4, and the ligand has the following structural formula.

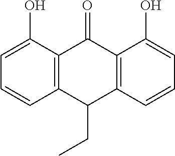 [SMILES: CCC1c2cccc(O)c2C(=O)c2c(O)cccc21]

### EXAMPLE 14

The scheme of this Example is similar to that of Example 1 except that the ligand is 9(10H)-Anthracenone, 10-bromo-1,8-dihydroxy-, the CAS number of the ligand is 2891-30-7, and the ligand has the following structural formula.

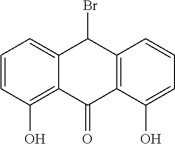 [SMILES: O=C1c2c(O)cccc2C(Br)c2cccc(O)c21]

### EXAMPLE 15

The scheme of this Example is similar to that of Example 1 except that the ligand is 1-hydroxyanthrone, the CAS number of the ligand is 1715-81-7, and the ligand has the following structural formula.

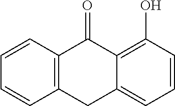 [SMILES: O=C1c2ccccc2Cc2cccc(O)c21]

### EXAMPLE 16

The scheme of this Example is similar to that of Example 1 except that the ligand is oxanthrone, the CAS number of the ligand is 549-99-5, and the ligand has the following structural formula.

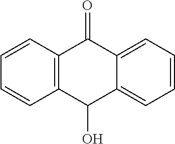 [SMILES: O=C1c2ccccc2C(O)c2ccccc21]

### EXAMPLE 17

The scheme of this Example is similar to that of Example 1 except that the ligand is anthracene-1,9-diol, the CAS number of the ligand is 30086-95-4, and the ligand has the following structural formula.

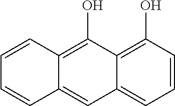 [SMILES: Oc1cccc2cc3ccccc3c(O)c12]

### EXAMPLE 18

The scheme of this Example is similar to that of Example 1 except that the ligand is anthracene-9,10-diol, the CAS number of the ligand is 4981-66-2, and the ligand has the following structural formula.

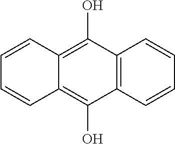 [SMILES: Oc1c2ccccc2c(O)c2ccccc12]

### EXAMPLE 19

The scheme of this Example is similar to that of Example 1 except that the ligand is 1,9,10-Anthracenetriol, the CAS number of the ligand is 27354-06-9, and the ligand has the following structural formula.

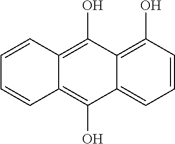 [SMILES: Oc1c2ccccc2c(O)c2c(O)cccc12]

### EXAMPLE 20

The scheme of this Example is similar to that of Example 1 except that the ligand is 1,4,5,8-Tetrahydroxy anthraquinone, the CAS number of the ligand is 81-60-7, and the ligand has the following structural formula.

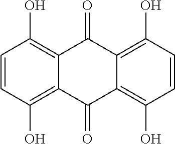 [SMILES: O=C1c2c(O)ccc(O)c2C(=O)c2c(O)ccc(O)c21]

### EXAMPLE 21

The scheme of this Example is similar to that of Example 1 except that the ligand is 1,4-dimethylanthraquinone, the CAS number of the ligand is 1519-36-4, and the ligand has the following structural formula.

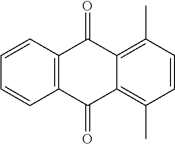 [SMILES: Cc1ccc(C)c2c1C(=O)c1ccccc1C2=O]

### EXAMPLE 22

The scheme of this Example is similar to that of Example 1 except that the ligand is a 1,4-dimethylanthraquinone derivative having the following structural formula.

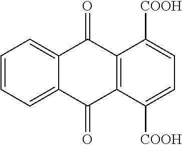

A method of preparing the ligand is as follows.

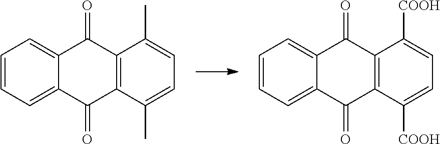 [SMILES: Cc1ccc(C)c2c1C(=O)c1ccccc1C2=O ; O=C(O)c1ccc(C(=O)O)c2c1C(=O)c1ccccc1C2=O]

1,4-dimethylanthraquinone (CAS: 1519-36-4) (10 mmol, 2.36 g) and chromium trioxide (CAS: 1333-82-0) (100 mmol, 10 g) were added to 100 ml of glacial acetic acid to give a mixture. The mixture was heated to 60° C. under stirring, refluxed for 10 hours, and the reaction was carried out to give the reaction product. After the reaction was completed, the reaction product was cooled to room temperature and filtered with suction to obtain a solid product. The solid product was dissolved in 10% of hot sodium hydroxide solution and filtered while hot to give a filtrate. After the filtrate was cooled, the pH value of the filtrate was adjusted to 2 with hydrochloric acid, and a solid was obtained by suction filtration. The solid was washed with acetone and dried in vacuo to give the product.

The product was identified and NMR data of the product was: ¹HNMR (500 MHZ, CDCl₃): 7.81 (d, J=6.8, 2H), 8.34 (d, J=6.8, 2H), 8.19 (s, 2H), 12.97 (s, 2H). The identification results showed that the product had the above structure and was the target compound-a 1,4-dimethylanthraquinone derivative.

### EXAMPLE 23

The scheme of this Example is similar to that of Example 1 except that the ligand is 1,4-Dichloro-9,10-anthraquinone, the CAS number of the ligand is 602-25-5, and the ligand has the following structural formula.

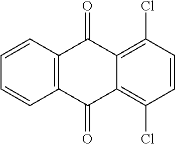 [SMILES: O=C1c2ccccc2C(=O)c2c(Cl)ccc(Cl)c21]

### EXAMPLE 24

The scheme of this Example is similar to that of Example 1 except that the ligand is 5-amino-1,4-dichloroanthraquinone, the CAS number of the ligand is 3223-94-7, and the ligand has the following structural formula.

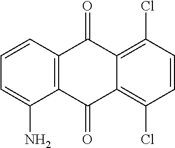 [SMILES: Nc1cccc2c1C(=O)c1c(Cl)ccc(Cl)c1C2=O]

### EXAMPLE 25

The scheme of this Example is similar to that of Example 1 except that the ligand is anthraquinone, the CAS number of the ligand is 84-65-1, and the ligand has the following structural formula.

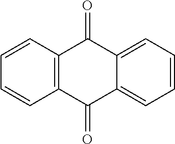 [SMILES: O=C1c2ccccc2C(=O)c2ccccc21]

### EXAMPLE 26

The scheme of this Example is similar to that of Example 1 except that the ligand is anthrone, the CAS number of the ligand is 90-44-8, and the ligand has the following structural formula.

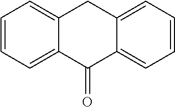 [SMILES: O=C1c2ccccc2Cc2ccccc21]

### EXAMPLE 27

The scheme of this Example is similar to that of Example 1 except that the ligand is anthranol, the CAS number of the ligand is 529-86-2, and the ligand has the following structural formula.

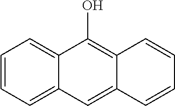 [SMILES: Oc1c2ccccc2cc2ccccc12]

### EXAMPLE 30

The scheme of this Example is similar to that of Example 1 except that the ligand is a mixture of an anthraquinone compound (9, 10-Anthracenedione, 1, 5-diamino-4a, 9a-dihydro, CAS No.: 1422011-39-9) and an anthrone compound (9 (10H)-Anthracenone, 10-bromo-1, 8-dihydroxy-, CAS No.: 2891-30-7) in a molar ratio of 1:1.

### EXAMPLE 31

The scheme of this Example is similar to that of Example 1 except that the ligand is a mixture of an anthraquinone compound (9, 10-Anthracenedione, 1, 5-diamino-4a, 9a-dihydro, CAS No.: 1422011-39-9) and an anthranol compound (1, 4, 5, 8-tetrahydroxyanthraquinone, CAS No.: 81-60-7) in a molar ratio of 1:1.

### EXAMPLE 32

The scheme of this Example is similar to that of Example 1 except that the ligand is a mixture of an anthranol compound (1, 4, 5, 8-tetrahydroxyanthraquinone, CAS No.: 81-60-7) and an anthrone compound (9 (10H)-Anthracenone, 10-bromo-1, 8-dihydroxy-, CAS No.: 2891-30-7) in a molar ratio of 1:1.

### COMPARATIVE EXAMPLE 1

The scheme of this Comparative Example 1 is similar to that of Example 1 except that the ligand is oleylamine.

The quantum dot light emitting diodes of Examples 1 to 32 and Comparative Example 1 were tested for external quantum efficiency EQE, turn-on voltage, and T95 life, and the test results are shown in Table 1.

The detection method of external quantum efficiency EQE is as follows. Using Fostar FPD optical characteristic measurement equipment, and controlling the efficiency testing system built by QE PRO spectrometer, Keithley 2400, and Keithley 6485 through LabView, parameters such as voltage, current, brightness, and luminescence spectrum were measured, and the external quantum efficiency EQE was calculated. Among them, the voltage when the brightness of a LED device reaches Inite is the turn-on voltage.

The detection method of T95 life is as follows. The test environment was 25° C., 60 RH %. A QLED device was driven at a constant current of 2 mA, and the brightness change of the QLED device was tested by a silicon photonic system, and the time required for the maximum brightness to decay from 100% to 95% after the device was powered on was recorded. The time required to obtain the brightness decay from 100% to 95% of the QLED device at the brightness of 1000 nit was calculated.

TABLE 1

| | turn-on | EQE | T [symbol] 9 [symbol] 5 [symbol] @ [symbol] 1 [symbol] |
|---|---|---|---|
| | voltage (V) | (%) | K [symbol] n [symbol] i [symbol] t [symbol] ( [symbol] h [symbol] ) |
| Example 1 | 1.58 | 14.8 | 4 [symbol] 6 [symbol] |
| Example 2 | 1.57 | 15.5 | 4 [symbol] 9 [symbol] |
| Example 3 | 1.62 | 15.8 | 4 [symbol] 2 [symbol] |
| Example 4 | 1.54 | 16 | 5 [symbol] 0 [symbol] |
| Example 5 | 1.5 | 16.2 | 5 [symbol] 2 [symbol] |
| Example 6 | 1.55 | 16.1 | 5 [symbol] 3 [symbol] |
| Example 7 | 1.5 | 16.3 | 5 [symbol] 5 [symbol] |
| Example 8 | 1.52 | 16 | 5 [symbol] 0 [symbol] |
| Example 9 | 1.5 | 16.2 | 5 [symbol] 3 [symbol] |
| Example 10 | 1.57 | 15.7 | 4 [symbol] 8 [symbol] |
| Example 11 | 1.65 | 14.5 | 4 [symbol] 5 [symbol] |
| Example 12 | 1.75 | 13 | 4 [symbol] 0 [symbol] |
| Example 13 | 1.7 | 13.8 | 4 [symbol] 5 [symbol] |
| Example 14 | 1.71 | 14 | 4 [symbol] 5 [symbol] |
| Example 15 | 1.69 | 14 | 4 [symbol] 0 [symbol] |
| Example 16 | 1.63 | 14.5 | 4 [symbol] 5 [symbol] |
| Example 17 | 1.69 | 14 | 4 [symbol] 0 [symbol] |
| Example 18 | 1.62 | 15.2 | 4 [symbol] 6 [symbol] |
| Example 19 | 1.57 | 15.7 | 5 [symbol] 0 [symbol] |
| Example 20 | 1.53 | 16.1 | 5 [symbol] 2 [symbol] |
| Example 21 | 1.61 | 15 | 4 [symbol] 6 [symbol] |
| Example 22 | 1.52 | 16 | 5 [symbol] 1 [symbol] |
| Example 23 | 1.59 | 15.7 | 4 [symbol] 9 [symbol] |
| Example 24 | 1.5 | 16.5 | 5 [symbol] 5 [symbol] |
| Example 25 | 1.75 | 13.5 | 3 [symbol] 8 [symbol] |
| Example 26 | 1.78 | 13 | 3 [symbol] 5 [symbol] |
| Example 27 | 1.8 | 13 | 3 [symbol] 4 [symbol] |
| Example 28 | 2.25 | 10.5 | 0 [symbol] . [symbol] 1 [symbol] |
| Example 29 | 1.65 | 15.5 | 5 [symbol] 0 [symbol] |
| Example 30 | 1.51 | 16.1 | 5 [symbol] 2 [symbol] |
| Example 31 | 1.67 | 15.5 | 5 [symbol] 0 [symbol] |
| Example 32 | 1.58 | 14.8 | 4 [symbol] 6 [symbol] |
| Comparative Example 1 | 1.57 | 15.5 | 4 [symbol] 9 [symbol] |

[symbol]

indicates data missing or illegible when filed

The light-emitting diode of each Example have higher luminous efficiency, lower turn-on voltage, and longer life than the light-emitting diode of Comparative Example 1. It can be seen that the use of the composite material of the present disclosure as a material of a light-emitting layer may effectively improve the light-emitting efficiency of the light-emitting diode, reduce the turn-on voltage of the light-emitting diode, and extend the service life thereof.

Comparing Examples 1 to 32, it can be seen that when the substituent contains a halogen group, a carboxyl group, an amino group, or a haloalkyl group, the device has a higher luminous efficiency, a lower turn-on voltage, and a longer life. In addition, comparing Examples 17 to 19 with Example 27, it can be seen that when the number of active groups increases, the luminous efficiency and lifetime of the device are improved accordingly, and the turn-on voltage is decreased accordingly; when at least one of R₁₉ to R₂₂ and R₂₅ contains the active group, the device has higher luminous efficiency, lower turn-on voltage, and longer life.

A composite material and a preparation method therefor, and a quantum dot light-emitting diode provided by embodiments of the present disclosure have been described in detail above, and specific examples have been applied herein to explain the principles and implementations of the present disclosure, and the description of the above embodiments is only for helping to understand the technical solutions and core ideas of the present disclosure. Those skilled in the art should understand that the technical solutions described in the above embodiments can still be modified, or some technical features can be equivalently replaced. However, these modifications or substitutions do not cause the essence of the corresponding technical solutions to deviate from the scope of the technical solutions of each embodiment of the present disclosure.

1. A composite material comprising a quantum dot and a ligand bound to a surface of the quantum dot, wherein the ligand is an anthracene compound, and the anthracene compound comprises at least one of anthraquinone, anthranol, anthrone, an anthraquinone derivative, an anthranol derivative, and an anthrone derivative.

2. The composite material according to claim 1, wherein the anthracene compound comprises at least one compound having a structure represented by any one of formulaes (1) to (3): 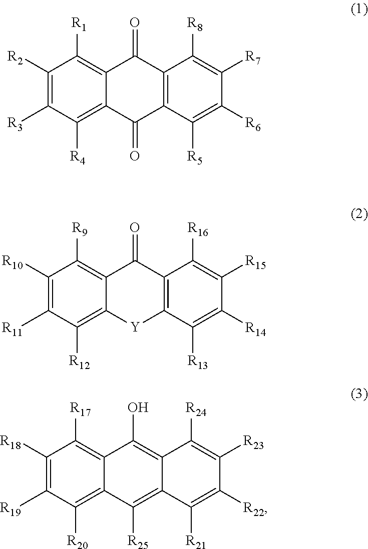
where Y is selected from CR₂₆R₂₇ or NR₂₈; R₁ to R₂₈ are independently selected from one or more of hydrogen, deuterium, alkyl, aryl, keto, cyano, hydroxyl, nitro, amino and halogen groups, or R₁ to R₂₈ are independently selected from one or more of the above groups and two adjacent substituents of R₁ to R₂₈ are bonded to form a ring.

3. The composite material according to claim 2, wherein carboxyl, amino, halogen or haloalkyl is set as an active group;
at least one of R₁ to R₈ is selected from active groups; and
at least one of R₁₇ to R₂₅ is selected from the active groups.

4. The composite material according to claim 3, wherein Y is selected from CR₂₆R₂₇, and at least one of R₉-R₁₆ and R₂₆-R₂₇ is selected from the active groups; or,
Y is selected from NR₂₈, and at least one of R₉ to R₁₆ and R₂₈ is selected from the active groups.

5. The composite material according to claim 4, wherein Y is selected from CR₂₆R₂₇, and at least one of R₁₁ to R₁₄ and R₂₆ to R₂₇ is selected from the active groups.

6. The composite material according to claim 4, wherein Y is selected from NR₂₈, and at least one of R₁₁ to R₁₄ and R₂₈ is selected from the active groups.

7. The composite material according to claim 3, wherein at least one of R₁₉ to R₂₂ and R₂₅ comprises the active group.

8. The composite material according to claim 2, wherein at least one of R₁-R₈ is selected from hydrogen or deuterium;
at least one of R₉ to R₁₆ is selected from hydrogen or deuterium; and
at least one of R₁₇ to R₂₅ is selected from hydrogen or deuterium.

9. The composite material according to claim 2, wherein the number of carbon atoms in the alkyl is less than or equal to 20; and
the number of ring atoms in the aryl is less than or equal to 60.

10. The composite material according to claim 2, wherein the anthracene compound comprises at least one compound having a structure represented by any one of the following structural formulas (4) to (30): 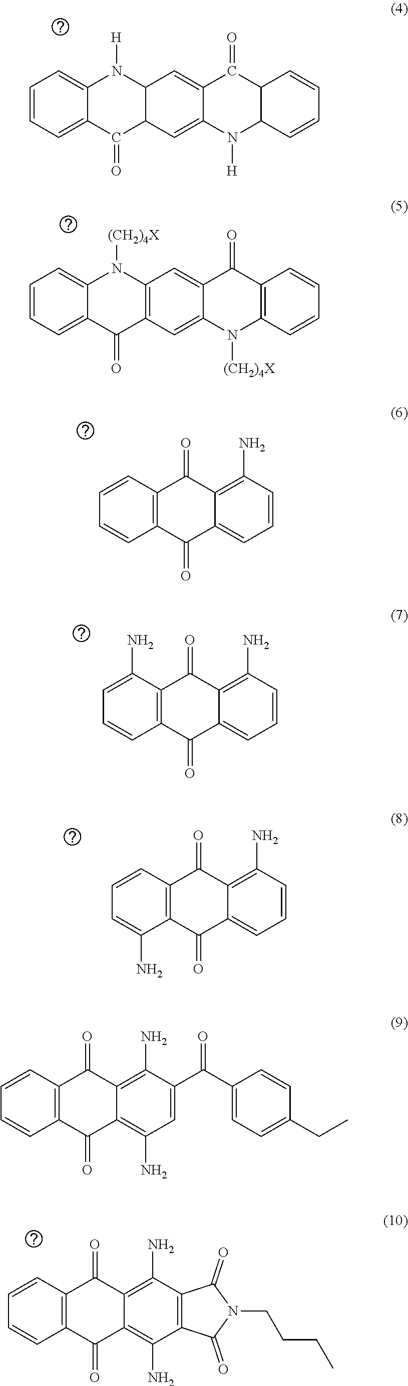 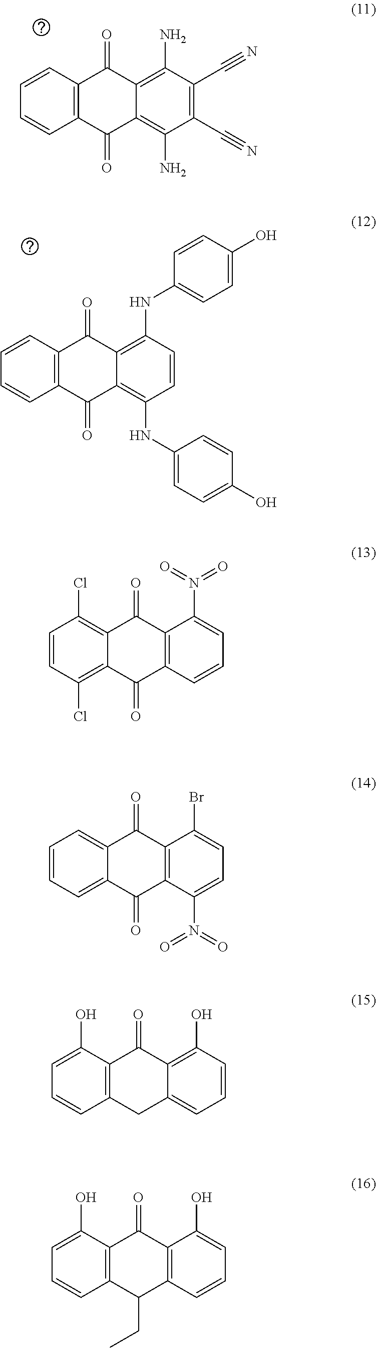 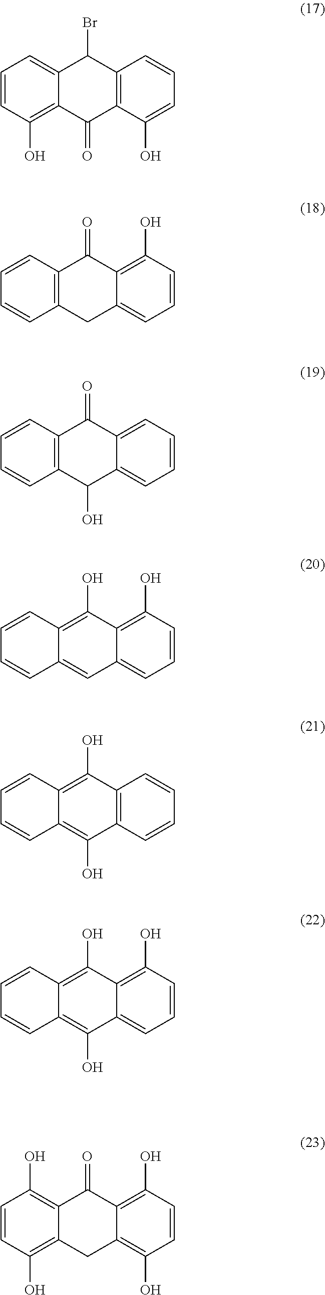 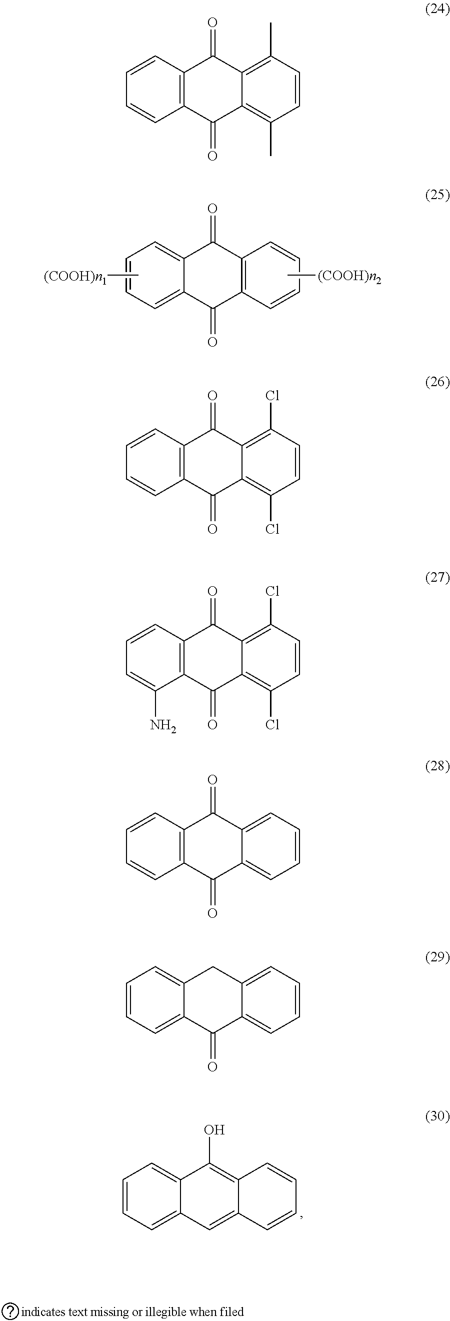
where n is a positive integer equal to or less than 20, X is Cl, Br, or I; n₁ and n₂ are independently selected from 0, 1, 2, 3 or 4, and the sum of n₁ and n₂ is greater than or equal to 1.

11. The composite material according to claim 1, wherein a molar ratio of the quantum dot and the ligand in the composite material is 1:(1 to 10); and
the quantum dot is selected from at least one of a single structure quantum dot and a core-shell structure quantum dot; the single structure quantum dot is selected from at least one of a group II-VI compound, a group IV-VI compound, a group III-V compound, and a group I-III-VI compound, the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb, the group I-III-VI compound is selected from one or more of CuInS₂, CuInSe₂, and AgInS₂; a core of the core-shell structure quantum dot is selected from any one of the single structure quantum dots, and a shell material of the core-shell structure quantum dot is selected from at least one of CdS, CdTe, CdSeTe, CdZnSe, CdZnS, CdSeS, ZnSe, ZnSeS, and ZnS.

12. A method for preparing a composite material, comprising:
providing a core cation precursor, a ligand, a core anion precursor, and an organic solvent;
mixing the core cation precursor, the ligand and the organic solvent, and then adding the core anion precursor to react to obtain a first solution containing a quantum dot core and the ligand; and,
injecting a shell cation source and a shell anion source into the first solution, forming a first shell layer on a surface of the quantum dot core, and repeating the steps n times to sequentially obtain a second shell layer to an (n+1)th shell layer to obtain a composite material in which the ligand is connected to a surface of the (n+1)th shell layer, wherein n is an integer equal to or greater than 0;
wherein the ligand is an anthracene compound, and the anthracene compound comprises at least one of anthraquinone, anthranol, anthrone, an anthraquinone derivative, an anthranol derivative, and an anthrone derivative.

13. The method according to claim 12, wherein the anthracene compound comprises at least one compound having a structure represented by any one of formulaes (1) to (3): 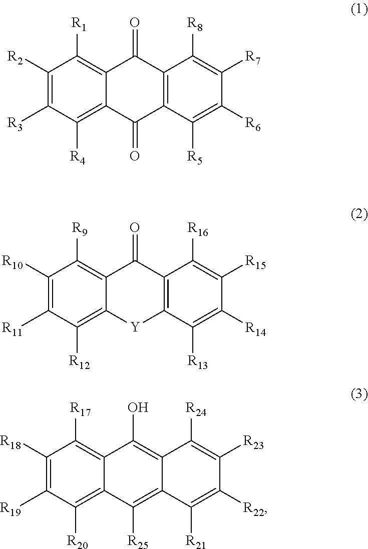
where Y is selected from CR₂₆R₂₇ or NR₂₈; R₁ to R₂₈ are independently selected from one or more of hydrogen, deuterium, alkyl, aryl, keto, cyano, hydroxyl, nitro, amino and halogen groups, or R₁ to R₂₈ are independently selected from one or more of the above groups and two adjacent substituents of R₁ to R₂₈ are bonded to form a ring.

14. The method according to claim 12, wherein the anthracene compound comprises at least one compound having a structure represented by any one of the following structural formulas (4) to (30): 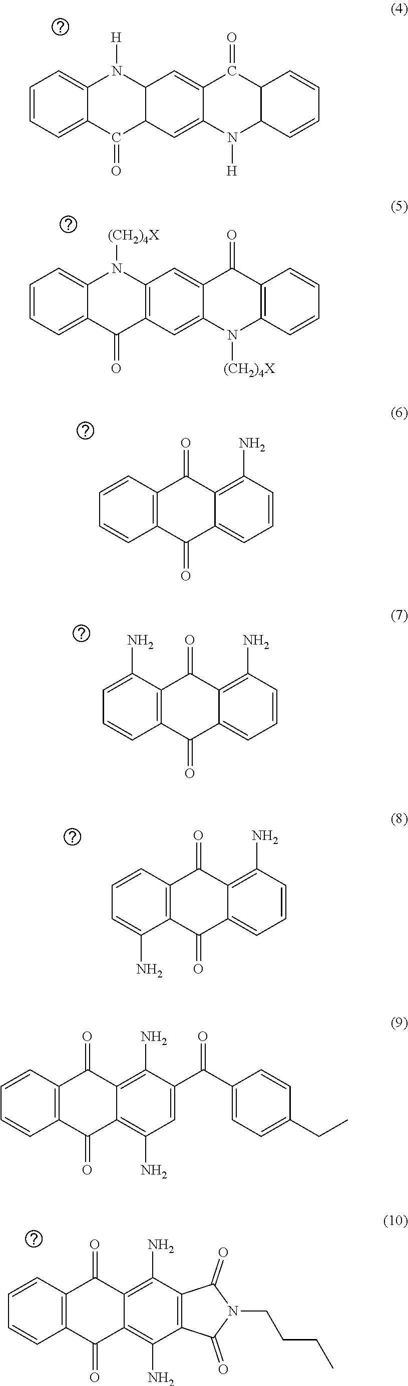 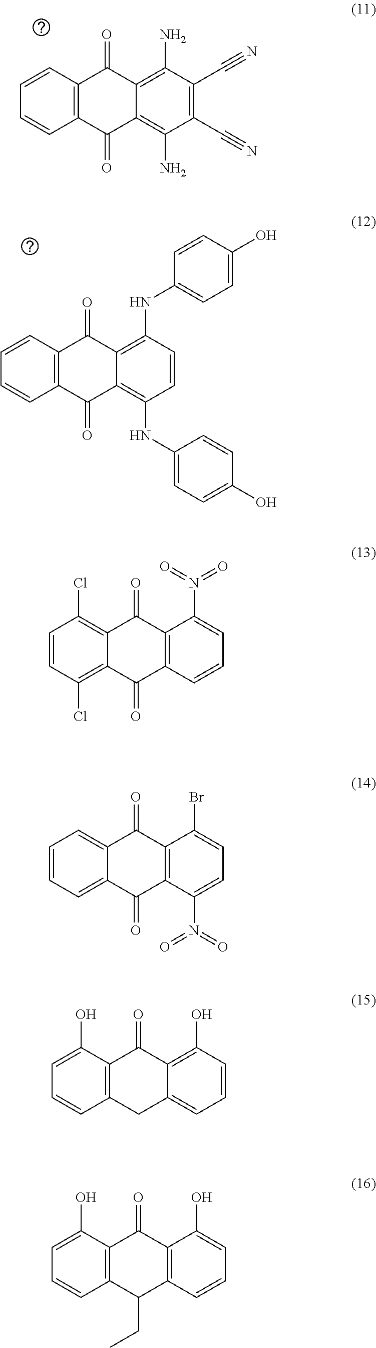 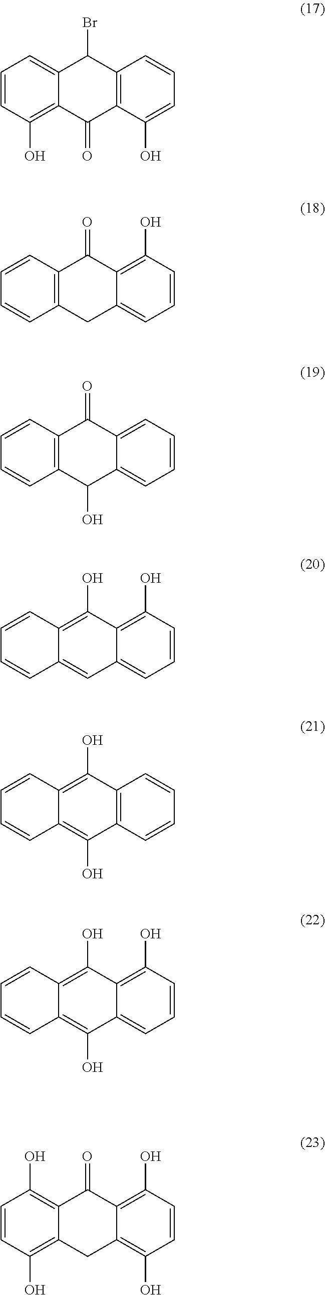 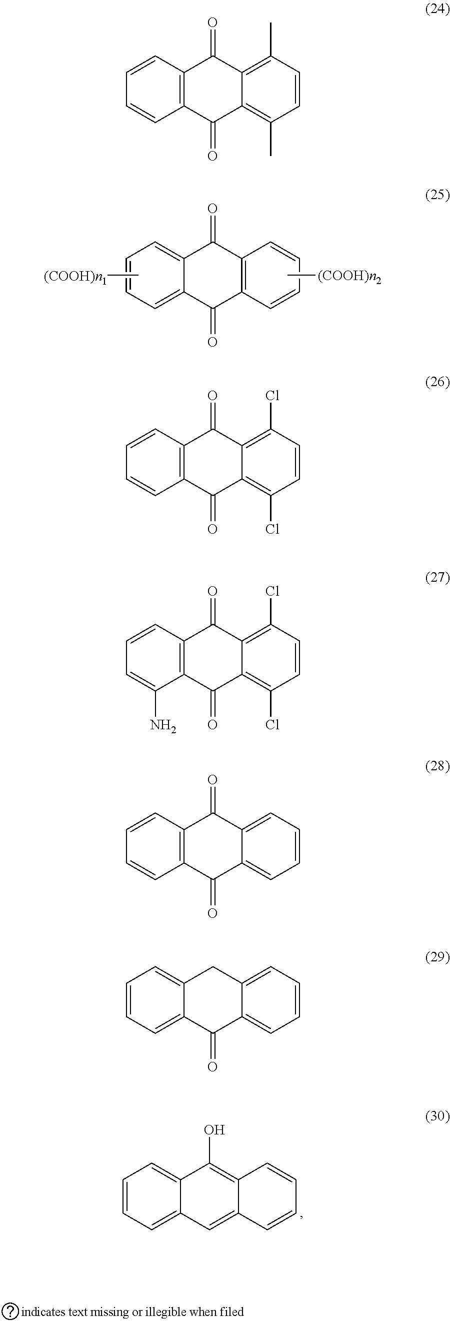
where n is a positive integer equal to or less than 20, X is Cl, Br, or I; n₁ and n₂ are independently selected from 0, 1, 2, 3 or 4, and a sum of n₁ and n₂ is greater than or equal to 1.

15. The method according to claim 14, wherein the ligand comprises a compound having a structure represented by structural formula (5);
prior to the step of providing the core cation precursor, the ligand, the core anion precursor, and the organic solvent, the method further comprising:
providing a first compound, quinacridone, sodium hydride, tetrabutylammonium bromide, and tetrahydrofuran, where the first compound has the structural formula X(CH₂)ₙX, with X being said Cl, Br or I; and,
mixing quinacridone, sodium hydride, tetrabutylammonium bromide and tetrahydrofuran, heating at 80-100° C., then adding the first compound, and continuing to heat at 50-70° C. to obtain a compound having the structure represented by structural formula (5).

16. The method according to claim 15, wherein a molar ratio of quinacridone, the first compound, sodium hydride, and tetrabutylammonium bromide is 1:(1-5):(5-8):(1-3);
a time of heating at 80-100° C. is 1-2 h; and
atime of heating at 50-70° C. is 12-24 h.

17. The method according to claim 14, wherein the ligand comprises a compound having a structure represented by structural formula (25);
prior to the step of providing the core cation precursor, the ligand, the core anion precursor, and the organic solvent, the method further comprising:
providing a second compound, glacial acetic acid, and chromium trioxide, where the second compound has a structure represented by formula (31), and a substitution site of —CH₃ in the second compound is the same as a substitution site of —COOH in the compound having a structure represented by structural formula (25); and,
mixing the second compound, glacial acetic acid, and chromium trioxide, and heating at 55 to 70° C., to obtain a compound having a structure represented by structural formula (25);
equation (31):

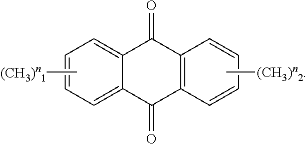

18. The method according to claim 12, wherein the core cation precursor comprises at least one of a cadmium source, a zinc source, an indium source, a copper source, and a silver source;
the core anion precursor comprises at least one of a selenium source, a sulfur source, a tellurium source, and a phosphorus source;
the organic solvent comprises an organic compound having 10 to 22 carbon atoms selected from at least one of alkanes, olefins, halogenated hydrocarbons, aromatic hydrocarbons, ethers, amines, ketones, and esters;
the shell cation source comprises at least one of a cadmium source and a zinc source;
the shell anion source comprises at least one of a selenium source, a sulfur source, a tellurium source, and a phosphorus source;
in the step of mixing the core cation precursor, the ligand and the organic solvent, and then adding the core anion precursor to react to obtain the first solution containing the quantum dot core and the ligand, a temperature of reacting is 180° C. to 320° C.; and,
the step of injecting a shell cation source and a shell anion source into the first solution, forming a first shell layer on a surface of the quantum dot core, and repeating the steps n times to sequentially obtain a second shell layer to an n+1-th shell layer to obtain a composite material in which the ligand is connected to a surface of the n+1-th shell layer, wherein n is an integer equal to or greater than 0, is performed at 240-320° C.

19. A quantum dot light-emitting diode comprising an anode, a light-emitting layer, and a cathode which are stacked, wherein a material of the light-emitting layer comprises a composite material comprising a quantum dot and a ligand bound to a surface of the quantum dot, the ligand being an anthracene compound, and the anthracene compound comprising at least one of anthraquinone, anthranol, anthrone, an anthraquinone derivative, an anthranol derivative, and an anthrone derivative.

20. The quantum dot light-emitting diode according to claim 19, wherein the anode and the cathode are independently selected from a metal electrode, a carbon-silicon material electrode, a metal oxide electrode, or a composite electrode, a material of the metal electrode is selected from at least one of Ag, Al, Mg, Au, Cu, Mo, Pt, Ca, and Ba, a material of the carbon-silicon material electrode is selected from at least one of silicon, graphite, carbon nanotubes, graphene, and carbon fiber, a material of the metal oxide electrode is selected from at least one of indium doped tin oxide, fluorine doped tin oxide, antimony doped tin oxide, aluminum doped zinc oxide, gallium doped zinc oxide, indium doped zinc oxide, magnesium doped zinc oxide and aluminum doped magnesium oxide, and the composite electrode is selected from at least one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS and ZnS/Al/ZnS.
